(19) United States
(12) Patent Application Publication
(10) Pub. No.: US 2020/0362097 A1
(43) Pub. Date: Nov. 19, 2020

(54) Chlorinated Benzodithiophene-based Polymers for Electronic and Photonic Applications

(71) Applicant: The Hong Kong University of Science and Technology, Hong Kong (CN)

(72) Inventors: He YAN, Hong Kong (CN); Ao SHANG, Hong Kong (CN)

(73) Assignee: The Hong Kong University of Science and Technology, Hong Kong (CN)

(21) Appl. No.: 15/733,141

(22) PCT Filed: Jan. 7, 2019
(86) PCT No.: PCT/CN2019/070614

§ 371 Date: May 28, 2020

Related U.S. Application Data
(60) Provisional application No. 62/709,173, filed on Jan. 10, 2018.

(51) Int. Cl. C08G 61/12; H01L 51/00

(52) U.S. Cl. CPC C08G 61/126; H01L 51/0043; H01L 51/0036; C08G 2261/124; C08G 2261/149; C08G 2261/1412; H01L 51/0566; C08G 2261/3243; C08G 2261/3246; C08G 2261/414; C08G 2261/512; C08G 2261/91; C08G 2261/3223

(57) ABSTRACT

Provided herein are polymers containing chlorinated benzodithiophene units, methods for their preparation and intermediates used therein, the use of formulations containing the same as semiconductors in organic electronic devices, especially in organic photovoltaic and organic field-effect transistor devices, and to organic electronic and organic photovoltaic devices made from these formulations.

### CROSS-REFERENCE TO RELATED APPLICATIONS

This application claims the benefit of priority of U.S. Provisional Application No. 62/709,173, filed on Jan. 10, 2018, the contents of which being hereby incorporated by reference in their entirety for all purposes.

### TECHNICAL FIELD

The present disclosure relates to polymers comprising chlorinated benzodithiophene units, methods for their preparation and intermediates used therein, the use of formulations comprising the same as semiconductors in organic electronic (OE) devices, especially in organic photovoltaic (OPV) and organic field-effect transistor (OFET) devices, and to OE and OPV devices made from these formulations.

### BACKGROUND

In recent years there has been growing interest in the use of organic semiconductors, including conjugated polymers, for various electronic applications.

One particular area of importance is the field of organic photovoltaics (OPV). Organic semiconductors (OSCs) have found use in OPV as they allow devices to be manufactured by solution-processing techniques, such as spin casting and printing. Solution processing can be carried out more economically and on a larger scale compared to evaporative techniques used to make inorganic thin film devices. State-of-the-art OPV cells typically include a photoactive layer containing a conjugated polymer and a fullerene derivative, which function as electron donor and electron acceptor, respectively. In order to achieve highly efficient OPVs, it is important to optimize both the donor and acceptor components and to find material combinations yielding an optimal bulk heterojunction (BHJ) morphology that supports efficient exciton harvesting and charge transport properties. Recent improvements in the efficiencies of single-junction OPVs (efficiency ˜13%) have largely been due to the development of benzodithiophene (BDT) based donor-acceptor polymers, which are defined as polymers including BDT units. Nonetheless, OPVs containing BDT based donor-acceptor materials can still suffer from low power conversion efficiencies (PCEs) and narrow light adsorption ranges. In an effort to improve the PCE and adsorption ranges of BDT based donor-acceptor materials, new low bandgap BDT based polymers were developed. In order to improve the absorption characteristics in the visible to near-infrared regions and better align the energy levels of low bandgap BDT based donor-acceptor polymers, novel small molecular acceptors (SMA), such as ITIC (3,9-bis(2-methylene-(3-(1,1-dicyanomethylene)-indanone))-5,5,11,11-tetrakis(4-hex ylphenyl)-dithieno[2,3-d:2′,3′-d′]-s-indaceno[1,2-b:5,6-b′]dithiophene) were developed.

Further efforts to improve the electronics of ITIC resulted in the development of even lower bandgap SMAs, such as ITIC-2F (FIG. 1), which shows a more red-shifted absorption than ITIC with an improved absorption coefficient in the visible to near-infrared regions. For this reason, devices with ITIC-2F acceptors can cover a broader absorption spectrum—which can potentially enhance the device PCEs. ITIC-2F also has deeper highest occupied molecular orbital (HOMO)/lowest unoccupied molecular orbital (LUMO) energy levels, which has stimulated the need for new BDT based donor-acceptor polymers with better energy alignment with new high efficiency lower energy SMAs, such as ITIC-2.

### SUMMARY

Provided herein are donor-acceptor materials comprising polymers having better electronic alignment with recent low energy SMAs, such as IT-4F. Also, provided are methods for their preparation and photoactive layers comprising the donor-acceptor materials described herein.

In a first aspect, provided herein is a donor-acceptor material comprising a polymer having a repeating unit of Formula I:

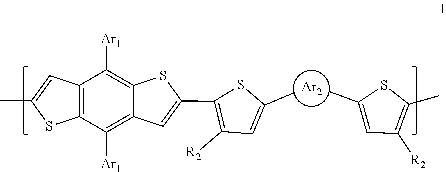

wherein Ar₁ is selected from the group consisting of:

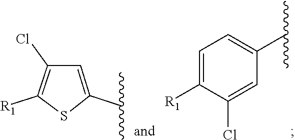

Ar₂ is selected from the group consisting of:

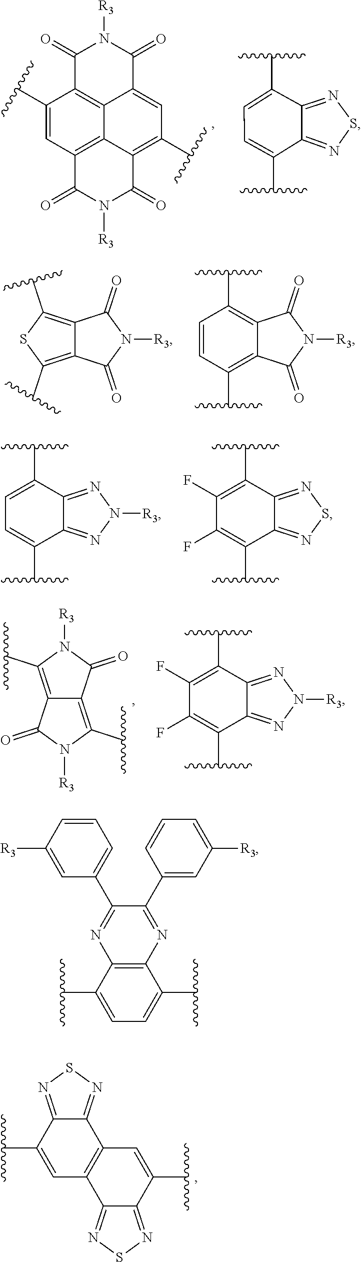

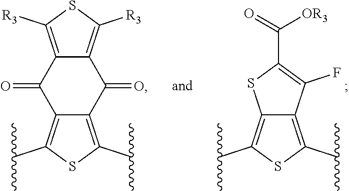

R₁ for each occurrence is independently selected from the group consisting of straight-chain, branched or cyclic alkyl groups with 2-40 C atoms, wherein one or more non-adjacent C atoms is optionally replaced by —O—, —S—, —(C═O)—, —C(═O)O—, —OC(═O)—, —O(C═O)O—, —CR₄═CR₄—, or —C≡C—, and one or more H atoms are optionally replaced by F, Cl, Br, I, CN, aryl, heteroaryl, aryloxy, heteroaryloxy, arylcarbonyl, heteroarylcarbonyl, arylcarbonyloxy, heteroarylcarbonyloxy, aryloxycarbonyl, or heteroaryloxycarbonyl having 4 to 30 ring atoms unsubstituted or substituted by one or more non-aromatic groups;

R₂ for each occurrence is independently selected from the group consisting of hydrogen, chloride, straight-chain, branched or cyclic alkyl groups with 2-40 C atoms, wherein one or more non-adjacent C atoms is optionally replaced by —O—, —S—, (C═O)—, —C(═O)O—, —OC(═O)—, —O(C═O)O—, —CR₄═CR₄—, or —C≡C—, and one or more H atoms are optionally replaced by F, Cl, Br, I, CN, aryl, heteroaryl, aryloxy, heteroaryloxy, arylcarbonyl, heteroarylcarbonyl, arylcarbonyloxy, heteroarylcarbonyloxy, aryloxycarbonyl, or heteroaryloxycarbonyl having 4 to 30 ring atoms unsubstituted or substituted by one or more non-aromatic groups;

R₃ for each instance is independently alkyl; and

R₄ for each instance is independently hydrogen or alkyl.

In a first embodiment of the first aspect, provided herein is the donor-acceptor material of the first aspect, wherein R₂ for each occurrence is independently hydrogen or alkyl.

In a second embodiment of the first aspect, provided herein is the donor-acceptor material of the first embodiment of the first aspect, wherein R₁ is alkyl.

In a third embodiment of the first aspect, provided herein is the donor-acceptor material of the second embodiment of the first aspect, wherein Ar₁ is:

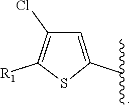

In a fourth embodiment of the first aspect, provided herein is the donor-acceptor material of the second embodiment of the first aspect, wherein the polymer has a repeating unit of Formula II:

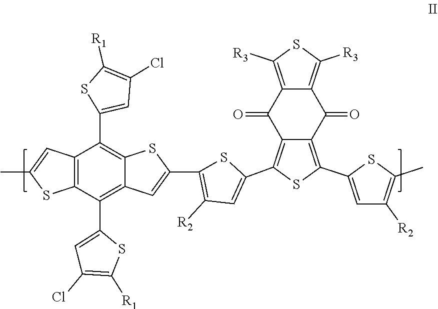

or Formula III:

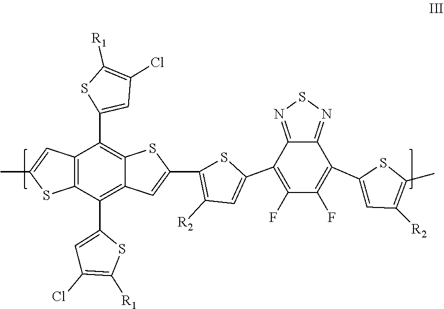

wherein R₁ is C₄-C₂₀ alkyl;

R₂ is hydrogen or C₄-C₂₀ alkyl; and

R₃ is C₄-C₂₀ alkyl.

In a fifth embodiment of the first aspect, provided herein is the donor-acceptor material of the first aspect, wherein the polymer has a repeating unit represented by:

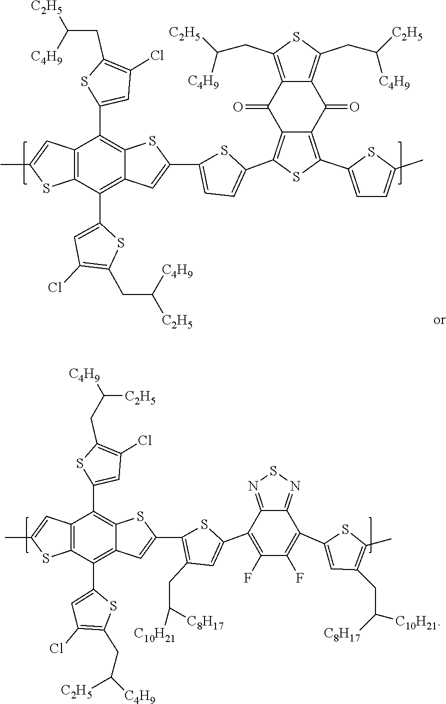

In a sixth embodiment of the first aspect, provided herein is the donor-acceptor material of the first aspect, wherein R₂ is chloride and Ar₁ is:

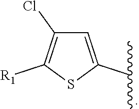

In a seventh embodiment of the first aspect, provided herein is the donor-acceptor material of the sixth embodiment of the first aspect, wherein R₁ is alkyl.

In an eighth embodiment of the first aspect, provided herein is the donor-acceptor material of the seventh embodiment of the first aspect, wherein the polymer has a repeating unit of Formula IV:

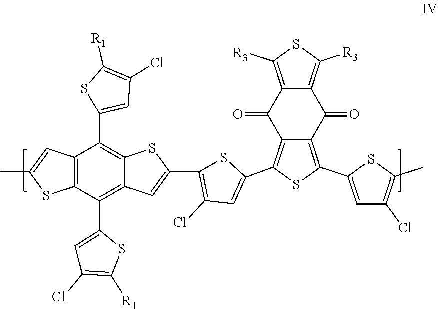

### or Formula V:

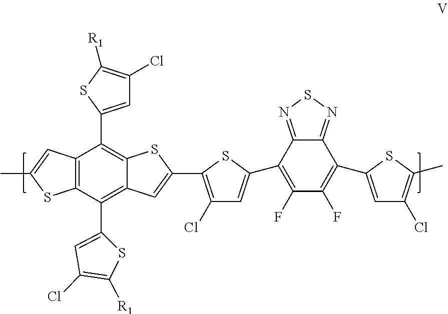

wherein R₁ is C₄-C₂₀ alkyl; and

R₃ is C₄-C₂₀ alkyl.

In a ninth embodiment of the first aspect, provided herein is the donor-acceptor material of the eighth embodiment of the first aspect, wherein R₁ and R₃ are 2-ethylhexyl.

In a tenth embodiment of the first aspect, provided herein is the donor-acceptor material of the eighth embodiment of the first aspect, wherein the polymer has a repeating unit of Formula IV:

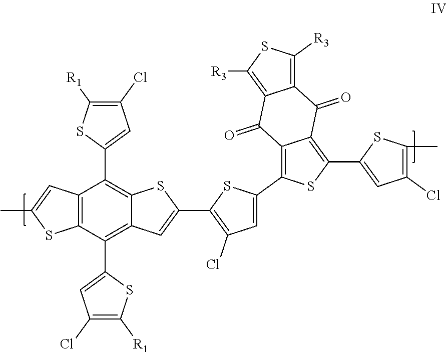

and further comprises a second repeating unit of Formula VI:

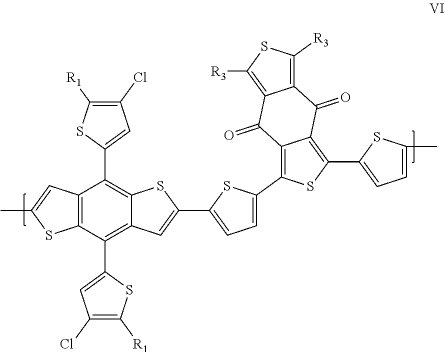

wherein R₁ is C₄-C₂₀ alkyl; and

R₃ is C₄-C₂₀ alkyl.

In an eleventh embodiment of the first aspect, provided herein is the donor-acceptor material of the tenth embodiment of the first aspect, wherein R₁ and R₃ are 2-ethylhexyl.

In a twelfth embodiment of the first aspect, provided herein is the donor-acceptor material of the tenth embodiment of the first aspect, wherein the molar ratio of the repeating unit of Formula IV and Formula VI is 0.2:1 to 0.7:1.

In a thirteenth embodiment of the first aspect, provided herein is the donor-acceptor material of the eighth embodiment of the first aspect, wherein the polymer has a repeating unit of Formula VI:

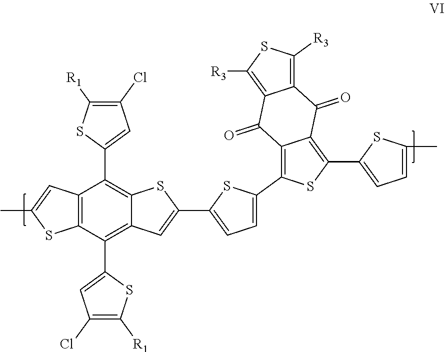

and further comprises a second repeating unit of Formula IX:

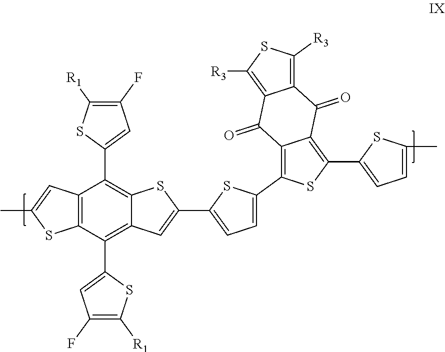

wherein R₁ is C₄-C₂₀ alkyl; and

R₃ is C₄-C₂₀ alkyl.

In a second aspect, provided herein is a photoactive layer comprising at least one donor-acceptor material of the first aspect and at least one small molecular acceptor (SMA) of Formula X:

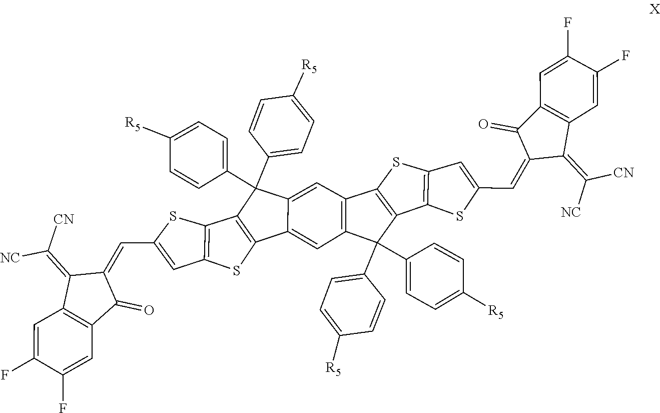

wherein R₅ for each occurrence is independently alkyl.

In a first embodiment of the second aspect, provided herein is the photoactive layer of the second aspect, wherein the least one donor-acceptor material is a polymer having a repeating unit of Formula II:

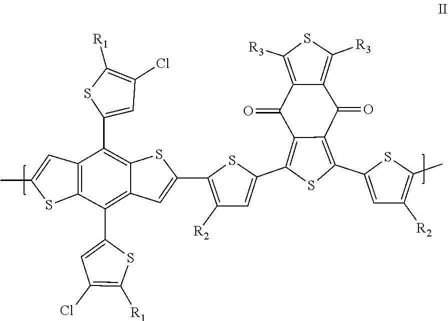

### or Formula III:

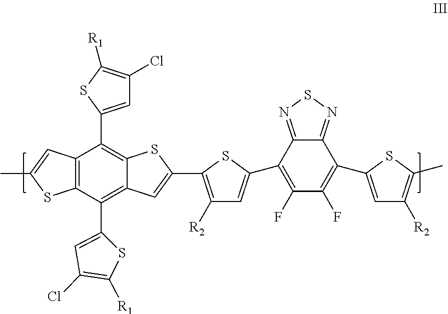

wherein R₁ is C₄-C₂₀ alkyl;

R₂ is hydrogen or C₄-C₂₀ alkyl; and

R₃ is C₄-C₂₀ alkyl.

In a second embodiment of the second aspect, provided herein is the photoactive layer of the second aspect, wherein the least one donor-acceptor material is a polymer having a repeating unit of Formula IV:

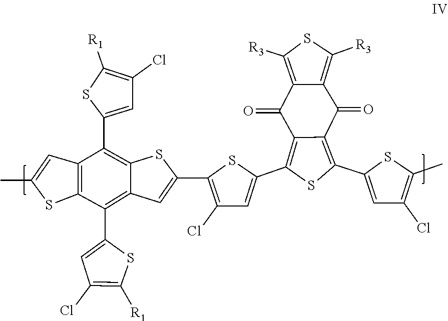

### or Formula V:

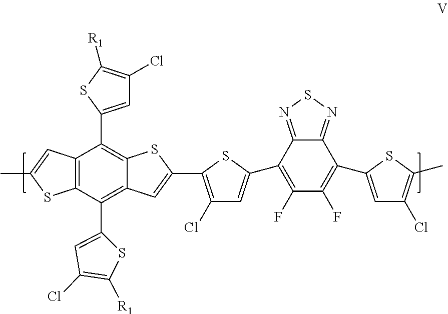

wherein R₁ is C₄-C₂₀ alkyl; and

R₃ is C₄-C₂₀ alkyl.

In a third embodiment of the second aspect, provided herein is the photoactive layer of the second aspect, wherein the least one donor-acceptor material is a polymer having a repeating unit of Formula IV:

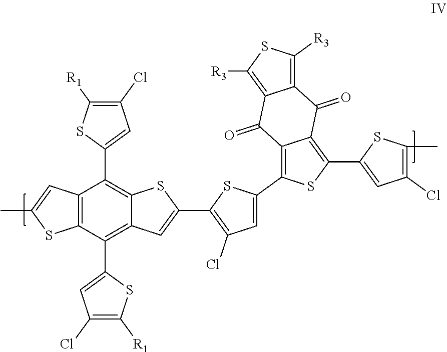

and further comprises a second repeating unit of Formula VI:

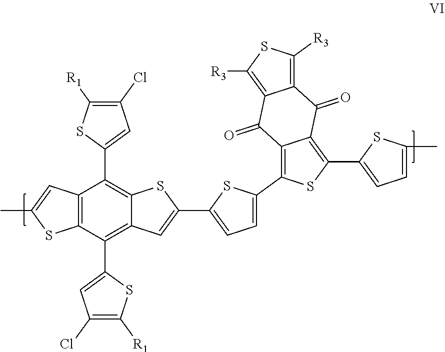

wherein R₁ is C₄-C₂₀ alkyl; and

R₃ is C₄-C₂₀ alkyl; or

a polymer having a repeating unit of Formula VI:

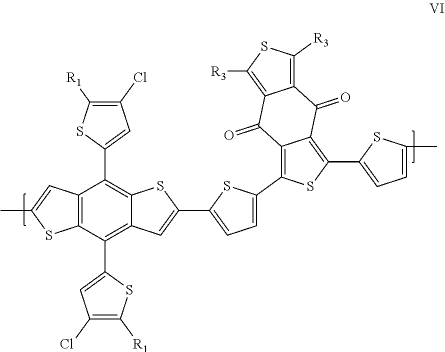

and further comprises a second repeating unit of Formula IX:

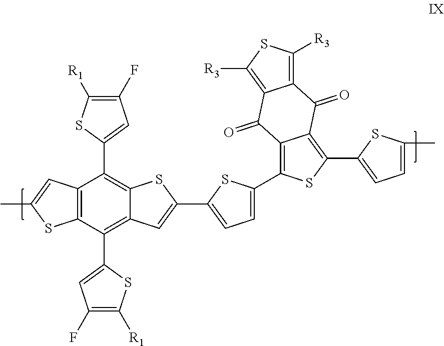

wherein R₁ is C₄-C₂₀ alkyl; and

R₃ is C₄-C₂₀ alkyl.

A photovoltaic cell comprising the photoactive layer of the second aspect.

A photovoltaic cell comprising the photoactive layer of the second embodiment of the second aspect.

A photovoltaic cell comprising the photoactive layer of the third embodiment of the second aspect.

The present subject matter further relates to an OE device prepared from a formulation as described herein. The OE devices contemplated in this regard include, without limitation, organic field effect transistors (OFET), integrated circuits (IC), thin film transistors (TFT), Radio Frequency Identification (RFID) tags, organic light emitting diodes (OLED), organic light emitting transistors (OLET), electroluminescent displays, organic photovoltaic (OPV) cells, organic solar cells (O-SC), flexible OPVs and O-SCs, organic laser diodes (O-laser), organic integrated circuits (O-IC), lighting devices, sensor devices, electrode materials, photoconductors, photodetectors, electrophotographic recording devices, capacitors, charge injection layers, Schottky diodes, planarising layers, antistatic films, conducting substrates, conducting patterns, photoconductors, electrophotographic devices, organic memory devices, biosensors and biochips.

### BRIEF DESCRIPTION OF THE DRAWINGS

It should be understood that the drawings described above or below are for illustration purposes only. The drawings are not necessarily to scale, with emphasis generally being placed upon illustrating the principles of the present teachings. The drawings are not intended to limit the scope of the present teachings in any way.

FIG. 1 depicts the chemical structures of exemplary donor-acceptor materials PBDDTh-BDTEHCl, PBDDThCl-BDTEHCl, and 0.5PBDDThCl-BDTEHCl, and exemplary small molecular acceptor ITIC-2F.

FIG. 2A depicts a cyclic voltammetry graph of exemplary donor-acceptor material PBDB-T-2Cl and comparative donor-acceptor material PBDB-T-2Cl.

FIG. 2B depicts the UV-Vis spectra of exemplary donor-acceptor material PBDB-T-2Cl and comparative donor-acceptor material PBDB-T-2Cl.

FIG. 3 depicts the UV-Vis spectra of an exemplary donor-acceptor material PFFBT-OD-BDTCl carried out using a DCB solution of the donor-acceptor material with the onset of the absorption indicated.

FIG. 4 depicts a schematic of an exemplary schematic of a single junction photovoltaic cell in accordance with certain embodiments as described herein.

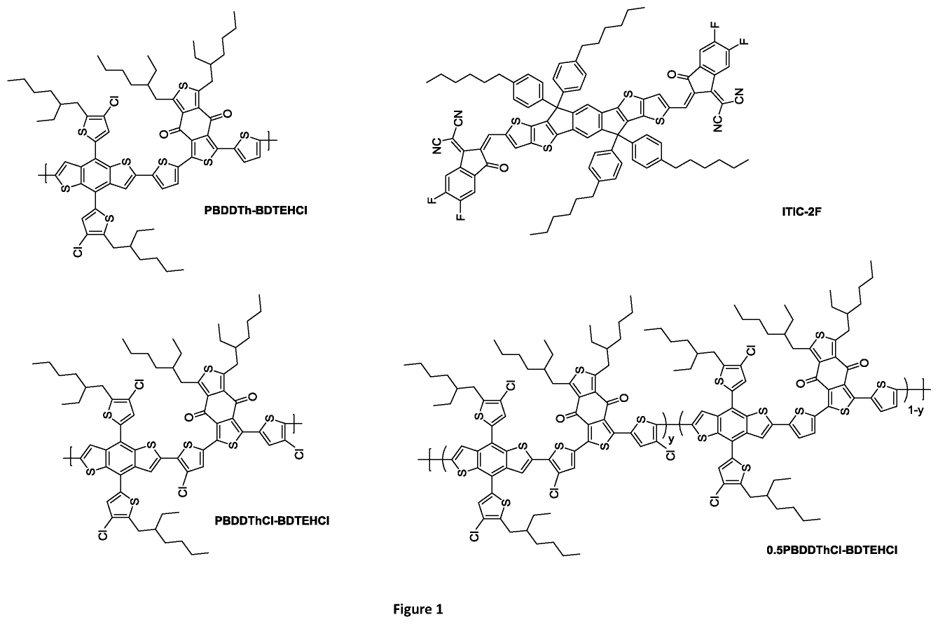

### DETAILED DESCRIPTION

Throughout the application, where compositions are described as having, including, or comprising specific components, or where processes are described as having, including, or comprising specific process steps, it is contemplated that compositions of the present teachings can also consist essentially of, or consist of, the recited components, and that the processes of the present teachings can also consist essentially of, or consist of, the recited process steps.

In the application, where an element or component is said to be included in and/or selected from a list of recited elements or components, it should be understood that the element or component can be any one of the recited elements or components, or the element or component can be selected from a group consisting of two or more of the recited elements or components. Further, it should be understood that elements and/or features of a composition, an apparatus, or a method described herein can be combined in a variety of ways without departing from the spirit and scope of the present teachings, whether explicit or implicit herein

The use of the terms “include,” “includes”, “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10% variation from the nominal value unless otherwise indicated or inferred.

It should be understood that the order of steps or order for performing certain actions is immaterial so long as the present teachings remain operable. Moreover, two or more steps or actions may be conducted simultaneously.

As used herein, a “p-type semiconductor material” or a “donor” material refers to a semiconductor material, for example, an organic semiconductor material, having holes as the majority current or charge carriers. In some embodiments, when a p-type semiconductor material is deposited on a substrate, it can provide a hole mobility in excess of about 10⁻⁵ cm²/Vs. In the case of field-effect devices, a p-type semiconductor also can exhibit a current on/off ratio of greater than about 10.

As used herein, an “n-type semiconductor material” or an “acceptor” material refers to a semiconductor material, for example, an organic semiconductor material, having electrons as the majority current or charge carriers. In some embodiments, when an n-type semiconductor material is deposited on a substrate, it can provide an electron mobility in excess of about 10⁻⁵ cm²/Vs. In the case of field-effect devices, an n-type semiconductor also can exhibit a current on/off ratio of greater than about 10.

As used herein, “mobility” refers to a measure of the velocity with which charge carriers, for example, holes (or units of positive charge) in the case of a p-type semiconductor material and electrons (or units of negative charge) in the case of an n-type semiconductor material, move through the material under the influence of an electric field. This parameter, which depends on the device architecture, can be measured using a field-effect device or space-charge limited current measurements.

As used herein, a compound can be considered “ambient stable” or “stable at ambient conditions” when a transistor incorporating the compound as its semiconducting material exhibits a carrier mobility that is maintained at about its initial measurement when the compound is exposed to ambient conditions, for example, air, ambient temperature, and humidity, over a period of time. For example, a compound can be described as ambient stable if a transistor incorporating the compound shows a carrier mobility that does not vary more than 20% or more than 10% from its initial value after exposure to ambient conditions, including, air, humidity and temperature, over a 3 day, 5 day, or 10 day period.

As used herein, fill factor (FF) is the ratio (given as a percentage) of the actual maximum obtainable power, (Pm or Vmp*Jmp), to the theoretical (not actually obtainable) power, (Jsc*Voc). Accordingly, FF can be determined using the equation:

FF=(Vmp*Jmp)/(Jsc*Voc)

where Jmp and Vmp represent the current density and voltage at the maximum power point (Pm), respectively, this point being obtained by varying the resistance in the circuit until J*V is at its greatest value; and Jsc and Voc represent the short circuit current and the open circuit voltage, respectively. Fill factor is a key parameter in evaluating the performance of solar cells. Commercial solar cells typically have a fill factor of about 0.60% or greater.

As used herein, the open-circuit voltage (Voc) is the difference in the electrical potentials between the anode and the cathode of a device when there is no external load connected.

As used herein, the power conversion efficiency (PCE) of a solar cell is the percentage of power converted from absorbed light to electrical energy. The PCE of a solar cell can be calculated by dividing the maximum power point (Pm) by the input light irradiance (E, in W/m2) under standard test conditions (STC) and the surface area of the solar cell (Ac in m2). STC typically refers to a temperature of 25° C. and an irradiance of 1000 W/m2 with an air mass 1.5 (AM 1.5) spectrum.

As used herein, a component (such as a thin film layer) can be considered “photoactive” if it contains one or more compounds that can absorb photons to produce excitons for the generation of a photocurrent.

As used herein, “solution-processable” refers to compounds (e.g., polymers), materials, or compositions that can be used in various solution-phase processes including spin-coating, printing (e.g., inkjet printing, gravure printing, offset printing and the like), spray coating, electrospray coating, drop casting, dip coating, blade coating, and the like.

As used herein, a “semicrystalline polymer” refers to a polymer that has an inherent tendency to crystallize at least partially either when cooled from a melted state or deposited from solution, when subjected to kinetically favorable conditions such as slow cooling, or low solvent evaporation rate and so forth. The crystallization or lack thereof can be readily identified by using several analytical methods, for example, differential scanning calorimetry (DSC) and/or X-ray diffraction (XRD).

As used herein, “annealing” refers to a post-deposition heat treatment to the semicrystalline polymer film in ambient or under reduced/increased pressure for a time duration of more than 100 seconds, and “annealing temperature” refers to the maximum temperature that the polymer film is exposed to for at least 60 seconds during this process of annealing. Without wishing to be bound by any particular theory, it is believed that annealing can result in an increase of crystallinity in the polymer film, where possible, thereby increasing field effect mobility. The increase in crystallinity can be monitored by several methods, for example, by comparing the differential scanning calorimetry (DSC) or X-ray diffraction (XRD) measurements of the as-deposited and the annealed films.

As used herein, a “polymeric compound” (or “polymer”) refers to a molecule including a plurality of one or more repeating units connected by covalent chemical bonds. A polymeric compound can be represented by General Formula I:

*-(-(Ma)ₓ-(Mb)_{y}-)_{z}* General Formula I

wherein each Ma and Mb is a repeating unit or monomer. The polymeric compound can have only one type of repeating unit as well as two or more types of different repeating units. When a polymeric compound has only one type of repeating unit, it can be referred to as a homopolymer. When a polymeric compound has two or more types of different repeating units, the term “copolymer” or “copolymeric compound” can be used instead. For example, a copolymeric compound can include repeating units where Ma and Mb represent two different repeating units. Unless specified otherwise, the assembly of the repeating units in the copolymer can be head-to-tail, head-to-head, or tail-to-tail. In addition, unless specified otherwise, the copolymer can be a random copolymer, an alternating copolymer, or a block copolymer. For example, General Formula I can be used to represent a copolymer of Ma and Mb having x mole fraction of Ma and y mole fraction of Mb in the copolymer, where the manner in which comonomers Ma and Mb is repeated can be alternating, random, regiorandom, regioregular, or in blocks, with up to z comonomers present. In addition to its composition, a polymeric compound can be further characterized by its degree of polymerization (n) and molar mass (e.g., number average molecular weight (M) and/or weight average molecular weight (Mw) depending on the measuring technique(s)).

As used herein, “halo” or “halogen” refers to fluoro, chloro, bromo, and iodo.

As used herein, “alkyl” refers to a straight-chain or branched saturated hydrocarbon group. Examples of alkyl groups include methyl (Me), ethyl (Et), propyl (e.g., n-propyl and z′-propyl), butyl (e.g., n-butyl, z′-butyl, sec-butyl, tert-butyl), pentyl groups (e.g., n-pentyl, z′-pentyl, -pentyl), hexyl groups, and the like. In various embodiments, an alkyl group can have 1 to 40 carbon atoms (i.e., C1-40 alkyl group), for example, 1-30 carbon atoms (i.e., C1-30 alkyl group). In some embodiments, an alkyl group can have 1 to 6 carbon atoms, and can be referred to as a “lower alkyl group.” Examples of lower alkyl groups include methyl, ethyl, propyl (e.g., n-propyl and z′-propyl), and butyl groups (e.g., n-butyl, z′-butyl, sec-butyl, tert-butyl). In some embodiments, alkyl groups can be substituted as described herein. An alkyl group is generally not substituted with another alkyl group, an alkenyl group, or an alkynyl group.

As used herein, “cycloalkyl” by itself or as part of another substituent means, unless otherwise stated, a monocyclic hydrocarbon having between 3-12 carbon atoms in the ring system and includes hydrogen, straight chain, branched chain, and/or cyclic substituents. Exemplary cycloalkyls include cyclopropyl, cyclobutyl, cyclopentyl, cyclohexyl, cycloheptyl, and the like.

As used herein, “alkenyl” refers to a straight-chain or branched alkyl group having one or more carbon-carbon double bonds. Examples of alkenyl groups include ethenyl, propenyl, butenyl, pentenyl, hexenyl, butadienyl, pentadienyl, hexadienyl groups, and the like. The one or more carbon-carbon double bonds can be internal (such as in 2-butene) or terminal (such as in 1-butene). In various embodiments, an alkenyl group can have 2 to 40 carbon atoms (i.e., C2-40 alkenyl group), for example, 2 to 20 carbon atoms (i.e., C2-20 alkenyl group). In some embodiments, alkenyl groups can be substituted as described herein. An alkenyl group is generally not substituted with another alkenyl group, an alkyl group, or an alkynyl group.

As used herein, a “fused ring” or a “fused ring moiety” refers to a polycyclic ring system having at least two rings where at least one of the rings is aromatic and such aromatic ring (carbocyclic or heterocyclic) has a bond in common with at least one other ring that can be aromatic or non-aromatic, and carbocyclic or heterocyclic. These polycyclic ring systems can be highly p-conjugated and optionally substituted as described herein.

As used herein, “heteroatom” refers to an atom of any element other than carbon or hydrogen and includes, for example, nitrogen, oxygen, silicon, sulfur, phosphorus, and selenium.

As used herein, “aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. An aryl group can have 6 to 24 carbon atoms in its ring system (e.g., C6-24 aryl group), which can include multiple fused rings. In some embodiments, a polycyclic aryl group can have 8 to 24 carbon atoms. Any suitable ring position of the aryl group can be covalently linked to the defined chemical structure. Examples of aryl groups having only aromatic carbocyclic ring(s) include phenyl, 1-naphthyl (bicyclic), 2-naphthyl (bicyclic), anthracenyl (tricyclic), phenanthrenyl (tricyclic), pentacenyl (pentacyclic), and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Other examples of aryl groups include benzodioxanyl, benzodioxolyl, chromanyl, indolinyl groups, and the like. In some embodiments, aryl groups can be substituted as described herein. In some embodiments, an aryl group can have one or more halogen substituents, and can be referred to as a “haloaryl” group. Perhaloaryl groups, i.e., aryl groups where all of the hydrogen atoms are replaced with halogen atoms (e.g., —C6F5), are included within the definition of “haloaryl.” In certain embodiments, an aryl group is substituted with another aryl group and can be referred to as a biaryl group. Each of the aryl groups in the biaryl group can be substituted as disclosed herein.

As used herein, “heteroaryl” refers to an aromatic monocyclic ring system containing at least one ring heteroatom selected from oxygen (O), nitrogen (N), sulfur (S), silicon (Si), and selenium (Se) or a polycyclic ring system where at least one of the rings present in the ring system is aromatic and contains at least one ring heteroatom. Polycyclic heteroaryl groups include those having two or more heteroaryl rings fused together, as well as those having at least one monocyclic heteroaryl ring fused to one or more aromatic carbocyclic rings, non-aromatic carbocyclic rings, and/or non-aromatic cycloheteroalkyl rings. A heteroaryl group, as a whole, can have, for example, 5 to 24 ring atoms and contain 1-5 ring heteroatoms (i.e., 5-20 membered heteroaryl group). The heteroaryl group can be attached to the defined chemical structure at any heteroatom or carbon atom that results in a stable structure. Generally, heteroaryl rings do not contain O—O, S—S, or S-0 bonds. However, one or more N or S atoms in a heteroaryl group can be oxidized (e.g., pyridine Noxide thiophene S-oxide, thiophene S,S-dioxide). Examples of heteroaryl groups include, for example, the 5- or 6-membered monocyclic and 5-6 bicyclic ring systems shown below: where T is O, S, NH, N-alkyl, N-aryl, N-(arylalkyl) (e.g., N-benzyl), SiH2, SiH(alkyl), Si(alkyl)₂, SiH(arylalkyl), Si(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzothiazolyl, benzisothiazolyl, benzisoxazolyl, benzoxadiazolyl, benzoxazolyl, cinnolinyl, 1H-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. In some embodiments, heteroaryl groups can be substituted as described herein.

The compounds described herein may include one or more groups that can exist as stereoisomers. All such stereoisomer isomers are contemplated by the present disclosure. In instances in which stereochemistry is indicated (for example E/Z double bond isomers), it is understood that for the sake of simplicity that only one stereoisomer is depicted. However, all stereoisomers and mixtures thereof are contemplated by the present disclosure.

The donor-acceptor materials described herein can generally be represented by a donor-acceptor material comprising a polymer having a repeating unit of the Formula I:

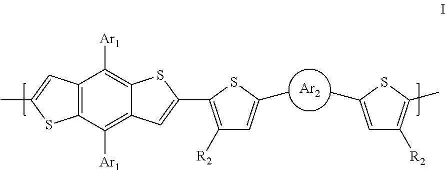

wherein Ar₁ is selected from the group consisting of:

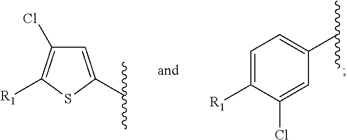

Ar₂ is selected from the group consisting of:

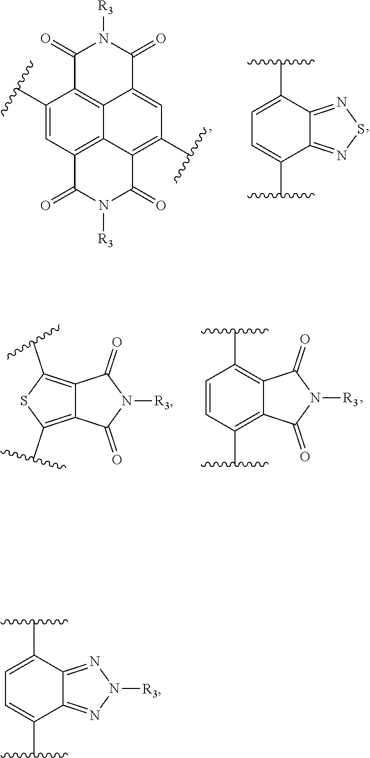

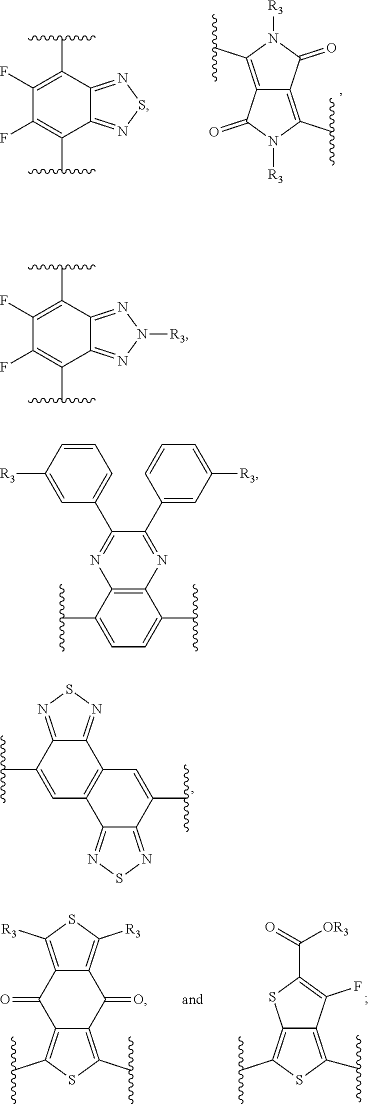

R₁ for each occurrence is independently selected from the group consisting of straight-chain, branched or cyclic alkyl groups with 2-40 C atoms, wherein one or more non-adjacent C atoms is optionally replaced by —O—, —S—, —(C═O)—, —C(═O)O—, —OC(═O)—, —O(C═O)O—, —CR₄═CR₄—, or —C≡C—, and one or more H atoms are optionally replaced by F, Cl, Br, I, CN, aryl, heteroaryl, aryloxy, heteroaryloxy, arylcarbonyl, heteroarylcarbonyl, arylcarbonyloxy, heteroarylcarbonyloxy, aryloxycarbonyl, or heteroaryloxycarbonyl having 4 to 30 ring atoms unsubstituted or substituted by one or more non-aromatic groups;

R₂ for each occurrence is independently selected from the group consisting of hydrogen, chloride, straight-chain, branched or cyclic alkyl groups with 2-40 C atoms, wherein one or more non-adjacent C atoms is optionally replaced by —O—, —S—, (C═O)—, —C(═O)O—, —OC(═O)—, —O(C═O)O—, —CR₄═CR₄—, or —C≡C—, and one or more H atoms are optionally replaced by F, Cl, Br, I, CN, aryl, heteroaryl, aryloxy, heteroaryloxy, arylcarbonyl, heteroarylcarbonyl, arylcarbonyloxy, heteroarylcarbonyloxy, aryloxycarbonyl, or heteroaryloxycarbonyl having 4 to 30 ring atoms unsubstituted or substituted by one or more non-aromatic groups;

R₃ for each instance is independently alkyl; and

R₄ for each instance is independently hydrogen or alkyl.

The polymer can comprise five or more repeating units as described herein. In certain embodiments, the polymer has an average molecular weight in the range of 10,000-1,000,000 gram/mole. In certain embodiments, the polymer has an average molecular weight in the range of 10,000-1,000,000; 10,000-900,000; 10,000-800,000; 10,000-700,000; 10,000-600,000; 10,000-500,000; 10,000-400,000; 10,000-300,000; 10,000-200,000; or 10,000-100,000 gram/mole.

In certain embodiments, Ar₂ is selected from the group consisting of:

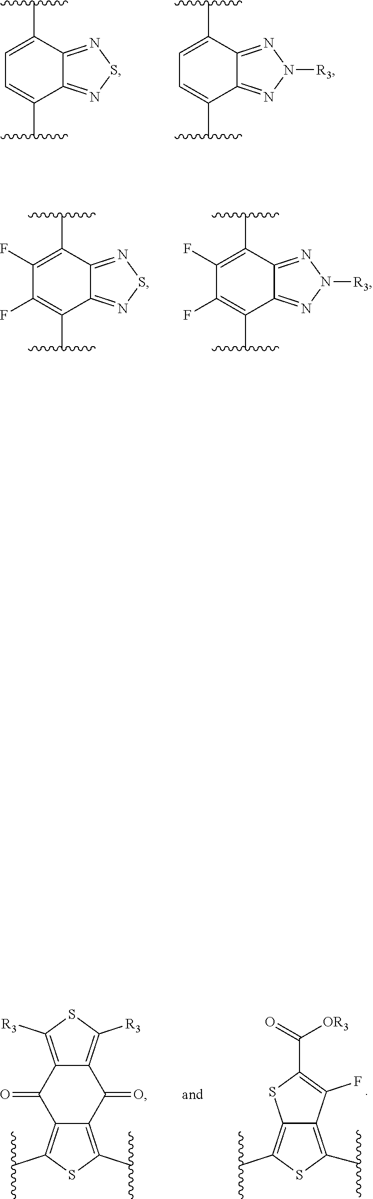

In certain embodiments, Ar₂ is selected from the group consisting of:

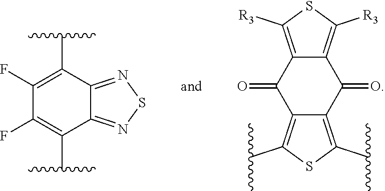

In certain embodiments, R₁ for each occurrence is independently alkyl. In certain embodiments, R₁ for each occurrence is selected from the group consisting of C₂-C₂₀ alkyl; C₂-C₁₈ alkyl; C₂-C₁₆ alkyl; C₂-C₁₄ alkyl; C₃-C₁₂ alkyl; C₄-C₁₄ alkyl; C₄-C₁₂ alkyl; C₄-C₁₀; and C₄-C₈ alkyl. In certain embodiments, R₁ is a moiety as shown below:

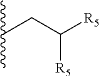

wherein each R₅ for each occurrence is independently C₁-C₁₆ alkyl. In certain embodiments, each R₅ is independently C₂-C₁₄ alkyl; C₂-C₁₂ alkyl; C₂-C₁₀ alkyl; C₂-C₈ alkyl; or C₂-C₆ alkyl.

In certain embodiments, R₂ for each occurrence is independently hydrogen or alkyl. In certain embodiments, R₂ for each occurrence is independently selected from the group consisting of hydrogen; chloride; C₂-C₂₀ alkyl; C₂-C₁₈ alkyl; C₂-C₁₆ alkyl; C₂-C₁₄ alkyl; C₄-C₁₄ alkyl; C₆-C₁₄ alkyl; C₈-C₁₄; C₈-C₁₀ alkyl; C₂-C₁₂ alkyl; C₂-C₁₀ alkyl; C₂-C₈ alkyl; and C₂-C₆ alkyl. In certain embodiments, each R₂ is hydrogen, chloride, or alkyl. In certain embodiments, R₂ is a moiety as shown below:

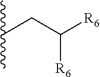

wherein each R₆ for each occurrence is independently C₁-C₁₆ alkyl. In certain embodiments, each R₆ is independently C₂-C₁₄ alkyl; C₄-C₁₄ alkyl; C₆-C₁₄ alkyl; C₆-C₁₂ alkyl; C₈-C₁₂ alkyl; or C₈-C₁₀ alkyl.

In certain embodiments, R₃ for each occurrence is independently alkyl. In certain embodiments, R₃ for each occurrence is selected from the group consisting of C₂-C₂₀ alkyl; C₂-C₁₈ alkyl; C₂-C₁₆ alkyl; C₂-C₁₄ alkyl; C₃-C₁₂ alkyl; C₄-C₁₄ alkyl; C₄-C₁₂ alkyl; C₄-C₁₀; and C₄-C₈ alkyl. In certain embodiments, R₃ is a moiety as shown below:

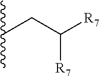

wherein each R₇ for each occurrence is independently C₁-C₁₆ alkyl. In certain embodiments, each R₇ is independently C₂-C₁₄ alkyl; C₂-C₁₂ alkyl; C₂-C₁₀ alkyl; C₂-C₈ alkyl; or C₂-C₆ alkyl.

R₄ for each occurrence can independently be hydrogen; C₁-C₂₀ alkyl; or C₃-C₈ cycloalkyl.

In certain embodiments, the donor-acceptor material comprises a polymer having five or more repeating units of the moiety shown below:

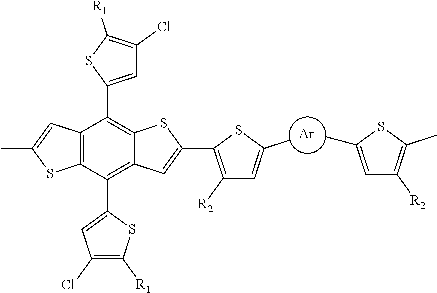

wherein Ar is selected from:

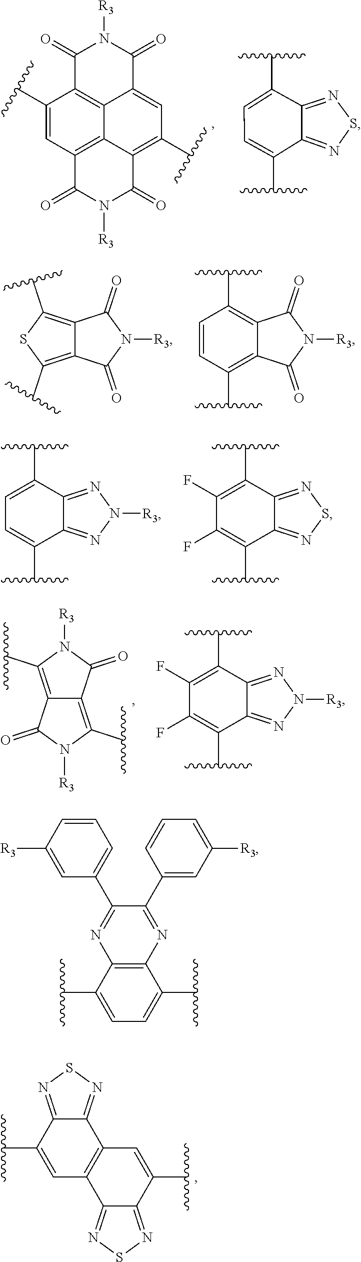

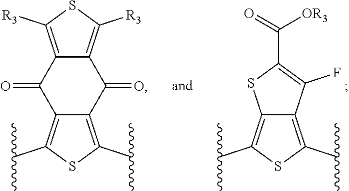

R₁ and R₂ are independently selected from straight-chain, branched or cyclic alkyl groups with 2-40 C atoms, in which one of more non-adjacent C atoms are optionally replaced by —O—, —S—, C(O)—, —C(O—)—O—, —O—C(O)—, —O—C(O)—O—, —CR0=CR00- or —C≡C— and in which one or more H atoms are optionally replaced by F, Cl, Br, I or CN, or denote aryl, heteroaryl, aryloxy, heteroaryloxy, arylcarbonyl, heteroarylcarbonyl, arylcarbonyloxy, heteroarylcarbonyloxy, aryloxycarbonyl or heteroaryloxycarbonyl having 4 to 30 ring atoms that is unsubstituted or substituted by one or more non-aromatic groups; R is alkyl; and R0 and R00 are independently hydrogen or alkyl.

In certain embodiments, the donor-acceptor material comprises a polymer having five or more repeating units of the moiety shown below:

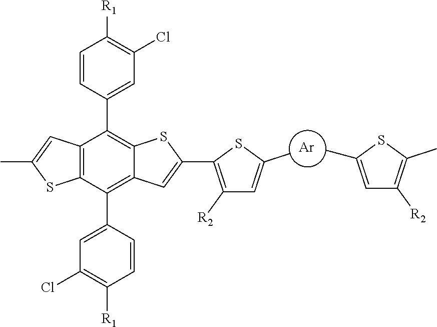

wherein Ar is selected from:

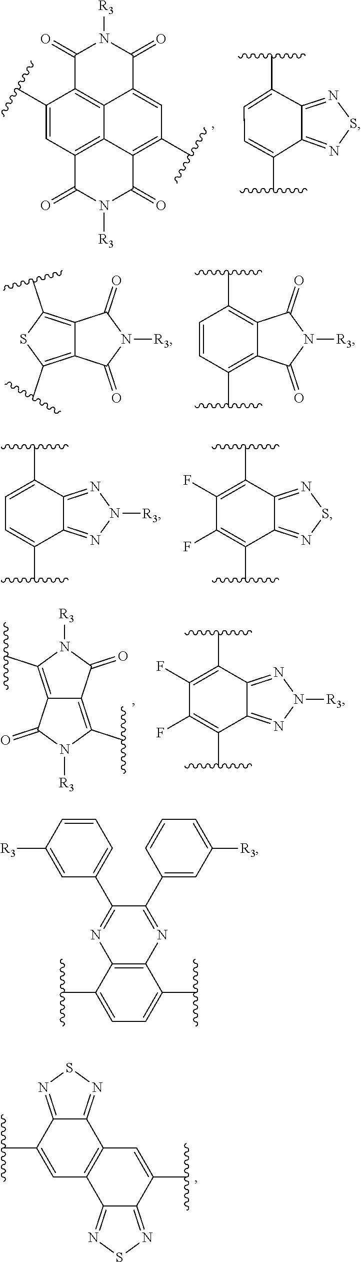

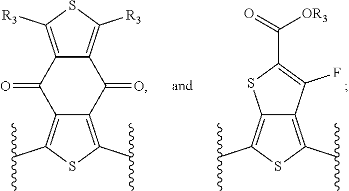

R₁ and R₂ are independently selected from straight-chain, branched or cyclic alkyl groups with 2-40 C atoms, in which one of more non-adjacent C atoms are optionally replaced by —O—, —S—, C(O)—, —C(O—)—O—, —O—C(O)—, —O—C(O)—O—, —CR0=CR00- or —C≡C— and in which one or more H atoms are optionally replaced by F, Cl, Br, I or CN, or denote aryl, heteroaryl, aryloxy, heteroaryloxy, arylcarbonyl, heteroarylcarbonyl, arylcarbonyloxy, heteroarylcarbonyloxy, aryloxycarbonyl or heteroaryloxycarbonyl having 4 to 30 ring atoms that is unsubstituted or substituted by one or more non-aromatic groups; R is alkyl; and R0 and R00 are independently hydrogen or alkyl.

In certain embodiments, the donor-acceptor material comprises a polymer having a repeating unit of Formula II or Formula III as shown below:

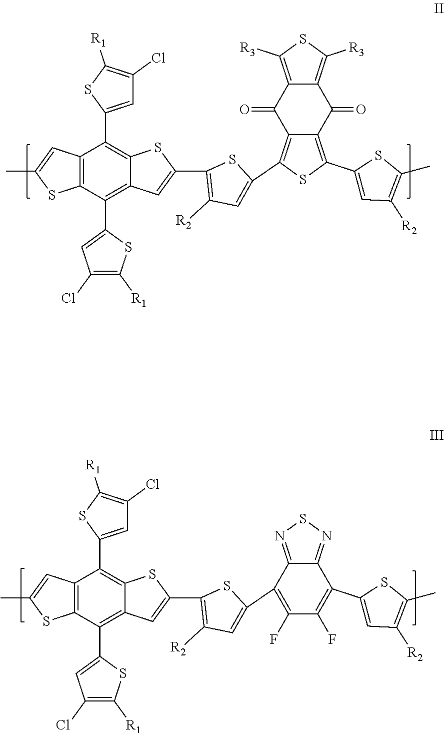

wherein R₁ is C₄-C₂₀ alkyl; R₂ is hydrogen or C₄-C₂₀ alkyl; and R₃ is C₄-C₂₀ alkyl.

In certain embodiments of the polymers having repeating units of Formula II or Formula III, R₁ for each occurrence is independently alkyl. In certain embodiments of the polymers having repeating units of Formula II or Formula III, R₁ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments of the polymers having repeating units of Formula II or Formula III, R₁ is a moiety as shown below:

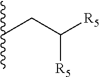

wherein each R₅ for each occurrence is independently C₁-C₁₆ alkyl. In certain embodiments, each R₅ is independently C₂-C₁₄ alkyl; C₂-C₁₂ alkyl; C₂-C₁₀ alkyl; C₂-C₈ alkyl; or C₂-C₆ alkyl.

In certain embodiments of the polymers having repeating units of Formula II or Formula III, R₂ is hydrogen.

In certain embodiments of the polymers having repeating units of Formula II or Formula III, R₂ is C₄-C₁₈ alkyl; C₄-C₁₆ alkyl; C₄-C₁₄ alkyl; C₆-C₁₄ alkyl; C₈-C₁₄; C₈-C₁₀ alkyl; C₄-C₁₂ alkyl; C₄-C₁₀ alkyl; C₄-C₈ alkyl; and C₄-C₆ alkyl. In certain embodiments, R₂ is a moiety as shown below:

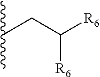

wherein each R₆ for each occurrence is independently C₁-C₁₆ alkyl. In certain embodiments, each R₆ is independently C₂-C₁₄ alkyl; C₄-C₁₄ alkyl; C₆-C₁₄ alkyl; C₆-C₁₂ alkyl; C₈-C₁₂ alkyl; or C₈-C₁₀ alkyl.

In certain embodiments of the polymers having repeating units of Formula II, R₃ is alkyl. In certain embodiments of the polymers having repeating units of Formula II, R₃ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments of the polymers having repeating units of Formula II, R₃ is a moiety as shown below:

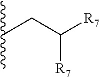

wherein each R₇ for each occurrence is independently C₁-C₁₆ alkyl. In certain embodiments, each R₇ is independently C₂-C₁₄ alkyl; C₂-C₁₂ alkyl; C₂-C₁₀ alkyl; C₂-C₈ alkyl; or C₂-C₆ alkyl.

In certain embodiments, the donor-acceptor material comprises a polymer having a repeating unit represented by:

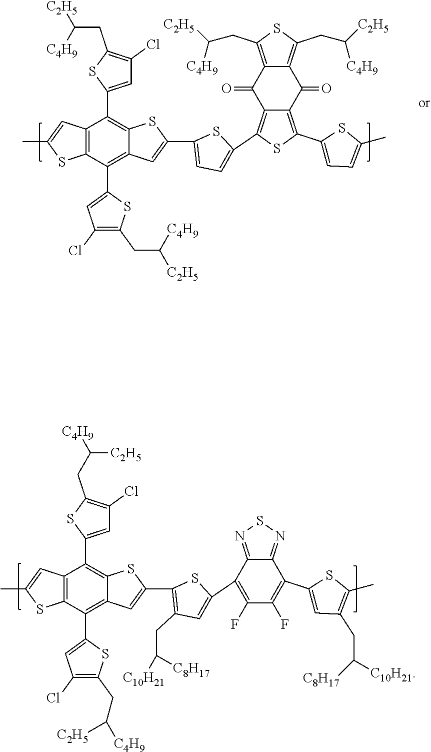

In certain embodiments, the donor-acceptor material comprises a polymer having a repeating unit represented by:

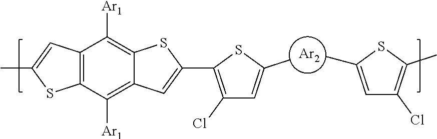

wherein Ar₁ and Ar₂ are as defined herein.

In certain embodiments, the donor-acceptor material comprises a polymer having a repeating unit represented by:

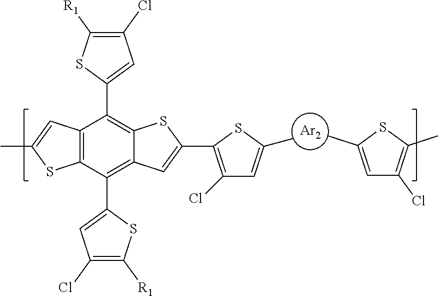

wherein R₁ and Ar₂ are as defined herein.

In certain embodiments, the donor-acceptor material comprises a polymer having a repeating unit of Formula IV or Formula V as shown below:

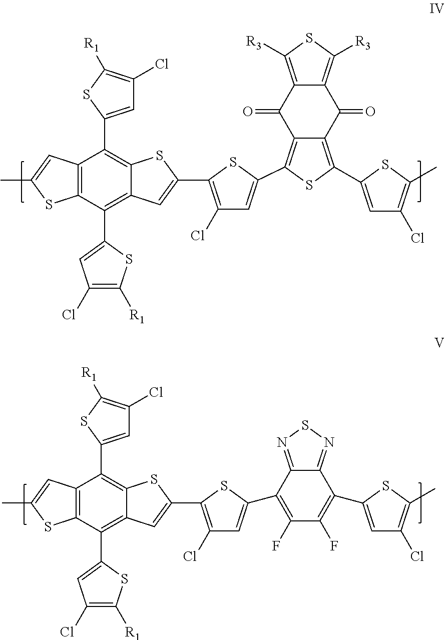

wherein R₁ is C₄-C₂₀ alkyl; and R₃ is C₄-C₂₀ alkyl.

In certain embodiments of the polymers having repeating units of Formula IV or Formula V, R₁ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments of the polymers having repeating units of Formula IV or Formula V, R₁ is a moiety as shown below:

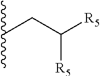

wherein each R₅ for each occurrence is independently C₁-C₁₆ alkyl. In certain embodiments, each R₅ is independently C₂-C₁₄ alkyl; C₂-C₁₂ alkyl; C₂-C₁₀ alkyl; C₂-C₈ alkyl; or C₂-C₆ alkyl.

In certain embodiments of the polymers having repeating units of Formula IV, R₃ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments of the polymers having repeating units of Formula IV, R₃ is a moiety as shown below:

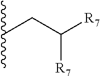

wherein each R₇ for each occurrence is independently C₁-C₁₆ alkyl. In certain embodiments of the polymers having repeating units of Formula IV, each R₇ is independently C₂-C₁₄ alkyl; C₂-C₁₂ alkyl; C₂-C₁₀ alkyl; C₂-C₈ alkyl; or C₂-C₆ alkyl.

In certain embodiments of the polymers having repeating units of Formula IV or Formula V, R₁ and R₃ are 2-ethylhexyl.

In certain embodiments, the donor-acceptor material is a copolymer comprising two or more repeating units. In such embodiments, the donor-acceptor material can comprise a repeating unit of Formula V and further comprises a second repeating unit of Formula VI as shown below:

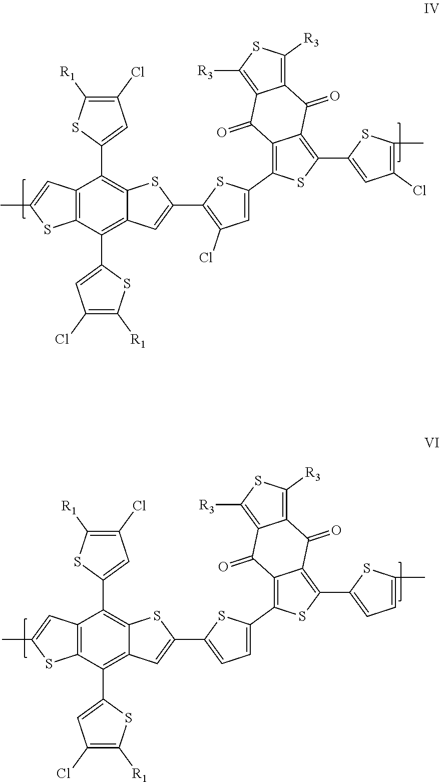

wherein R₁ is C₄-C₂₀ alkyl; and R₃ is C₄-C₂₀ alkyl.

In certain embodiments of the copolymer, the molar ratio of the repeating unit of Formula IV and the repeating unit of Formula VI is 0.1:1 to 1:0.1. In certain embodiments of the copolymer, the molar ratio of the repeating unit of Formula IV and the repeating unit of Formula VI is 1.5:1 to 1:1.5; 1.4:1 to 1:1.4; 1.3:1 to 1:1.3; 1.2:1 to 1:1.2; 1.1:1 to 1:1.1; or 1.05:1 to 1:1.05.

In certain embodiments of the copolymer, R₁ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments of the copolymer, R₁ is a moiety as shown below:

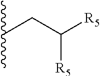

wherein each R₅ for each occurrence is independently C₁-C₁₆ alkyl. In certain embodiments of the copolymer, each R₅ is independently C₂-C₁₄ alkyl; C₂-C₁₂ alkyl; C₂-C₁₀ alkyl; C₂-C₈ alkyl; or C₂-C₆ alkyl.

In certain embodiments of the copolymer, R₃ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments of the copolymer, R₃ is a moiety as shown below:

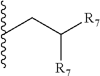

wherein each R₇ for each occurrence is independently C₁-C₁₆ alkyl. In certain embodiments of the copolymer, each R₇ is independently C₂-C₁₄ alkyl; C₂-C₁₂ alkyl; C₂-C₁₀ alkyl; C₂-C₈ alkyl; or C₂-C₆ alkyl.

In certain embodiments of the copolymer, R₁ and R₃ are 2-ethylhexyl.

In certain embodiments, the donor-acceptor material comprising a copolymer can be presented by Formula VIII:

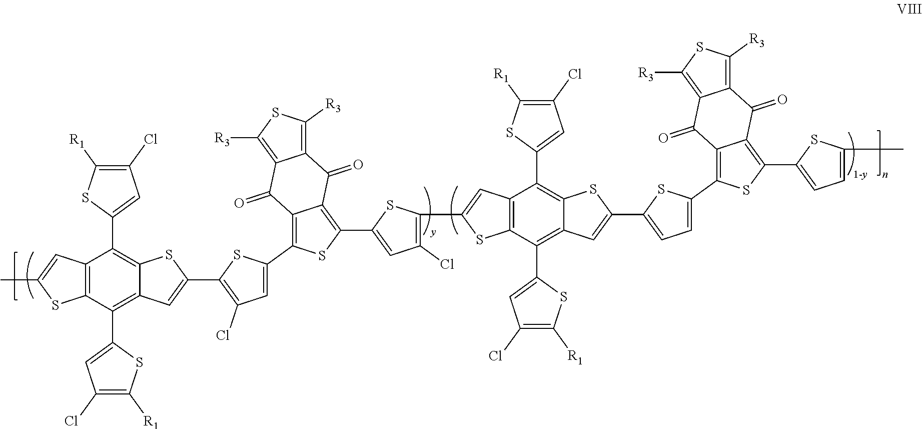

wherein n is 5 to 1,000;

y is 0.01 to 0.99;

R₁ is C₄-C₂₀ alkyl; and R₃ is C₄-C₂₀ alkyl

In certain embodiments, the donor-acceptor material comprising a copolymer can be presented by Formula VIII, y is 0.1-0.9; 0.2-0.8; 0.3-0.7; 0.4-0.6; or 0.45-0.55. In certain embodiments, the donor-acceptor material comprising a copolymer can be presented by Formula VIII, y is 0.5.

In certain embodiments, the donor-acceptor material comprising a copolymer can be presented by Formula VIII, R₁ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments, the donor-acceptor material comprising a copolymer can be presented by Formula VIII, R₁ is a moiety as shown below:

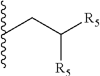

wherein each R₅ for each occurrence is independently C₁-C₁₆ alkyl. In certain embodiments, the donor-acceptor material comprising a copolymer can be presented by Formula VIII, each R₅ is independently C₂-C₁₄ alkyl; C₂-C₁₂ alkyl; C₂-C₁₀ alkyl; C₂-C₈ alkyl; or C₂-C₆ alkyl.

In certain embodiments, the donor-acceptor material comprising a copolymer can be presented by Formula VIII, R₃ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments, the donor-acceptor material comprising a copolymer can be presented by Formula VIII, R₃ is a moiety as shown below:

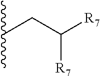

wherein each R₇ for each occurrence is independently C₁-C₁₆ alkyl. In certain embodiments, the donor-acceptor material comprising a copolymer can be presented by Formula VIII, each R₇ is independently C₂-C₁₄ alkyl; C₂-C₁₂ alkyl; C₂-C₁₀ alkyl; C₂-C₈ alkyl; or C₂-C₆ alkyl.

In certain embodiments, the donor-acceptor material comprising a copolymer can be presented by Formula VIII, R₁ and R₃ are 2-ethylhexyl.

In certain embodiments, the donor-acceptor material comprising a copolymer can be presented by Formula XI:

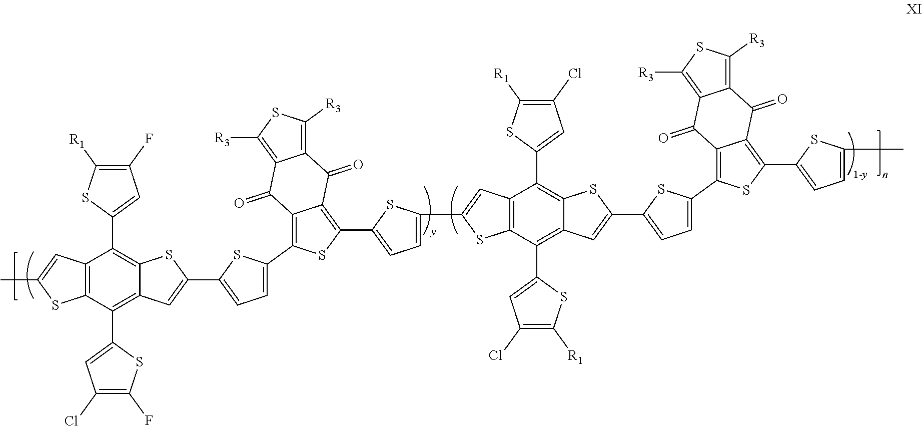

wherein n is 5 to 1,000;

y is 0.01 to 0.99;

R₁ is C₄-C₂₀ alkyl; and R₃ is C₄-C₂₀ alkyl

In certain embodiments, the donor-acceptor material comprising a copolymer can be presented by Formula XI, y is 0.1-0.9; 0.2-0.8; 0.3-0.7; 0.4-0.6; or 0.45-0.55. In certain embodiments, the donor-acceptor material comprising a copolymer can be presented by Formula XI, y is 0.5.

In certain embodiments, the donor-acceptor material comprising a copolymer can be presented by Formula XI, R₁ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments, the donor-acceptor material comprising a copolymer can be presented by Formula XI, R₁ is a moiety as shown below:

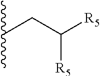

wherein each R₅ for each occurrence is independently C₁-C₁₆ alkyl. In certain embodiments, the donor-acceptor material comprising a copolymer can be presented by Formula XI, each R₅ is independently C₂-C₁₄ alkyl; C₂-C₁₂ alkyl; C₂-C₁₀ alkyl; C₂-C₈ alkyl; or C₂-C₆ alkyl.

In certain embodiments, the donor-acceptor material comprising a copolymer can be presented by Formula XI, R₃ for each occurrence is selected from the group consisting of C₄-C₁₈ alkyl; C₄-C₁₆ alkyl; C₄-C₁₄ alkyl; C₄-C₁₂ alkyl; C₄-C₁₀; and C₄-C₈ alkyl. In certain embodiments, the donor-acceptor material comprising a copolymer can be presented by Formula XI, R₃ is a moiety as shown below:

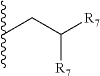

wherein each R₇ for each occurrence is independently C₁-C₁₆ alkyl. In certain embodiments, the donor-acceptor material comprising a copolymer can be presented by Formula XI, each R₇ is independently C₂-C₁₄ alkyl; C₂-C₁₂ alkyl; C₂-C₁₀ alkyl; C₂-C₈ alkyl; or C₂-C₆ alkyl.

In certain embodiments, the donor-acceptor material comprising a copolymer can be presented by Formula XI, R₁ and R₃ are 2-ethylhexyl.

In a previous report (X. Gao, J. L. Shen, B. Hu and G. L. Tu, Macromol. Chem. Phys, 2014, 215, 1388), chlorine-based monomers always lead to the formation of crosslinked copolymers in which the C—Cl bond participates in the Stille coupling polymerization reaction. It is known that Stille coupling polymerization reactions involving heteroaryl bromide coupling partners containing chloride can be problematic, as the C—Cl is known to take part in the coupling reaction resulting in undesired products. This issue can be exacerbated when the Stille coupling polymerization is conducted for prolonged periods at elevated temperatures, which may be necessary to ensure complete reaction and/or formation of Stille coupling polymerization products of the desired average molecular weight. In such instances, as the concentration of the C—Br coupling partner decreases over the reaction time, the relative rate of reaction of the C—Cl can increase, which can result in undesired coupling products. However, as demonstrated in the examples below, the donor-acceptor materials described herein can surprisingly be prepared in a highly efficient manner by employing a Stille coupling polymerization reaction under the specified conditions. In the examples below, the Stille coupling polymerization reaction is conducted under irradiation by microwaves in a sealed tube at elevated temperatures, which can accelerate the formation of unwanted coupling products, such as C—Cl coupling with the Ar—SnMe₃. Surprisingly, such coupling products were not observed.

Thus, also provided herein is a method of preparing a donor-acceptor material comprising a polymer having a repeating unit of Formula I comprising the step of:

contacting a compound represented by:

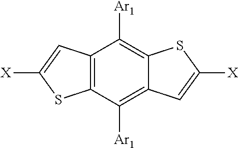

wherein X is Br, I, MsO, TfO, or OTs; and Ar₁ are as described herein; and
a compound represented by

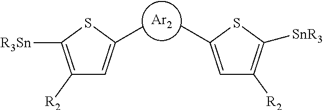

wherein R is alkyl; and Ar₂ and R₂ are defined as described herein in the presence of a catalyst thereby forming the donor-acceptor material comprising a polymer having a repeating unit of Formula I.

Suitable catalysts for Stille reactions typically are palladium based, but nickel can also be used. Examples of suitable catalysts include, but are not limited to, PdCl₂(PPh₃)₂, Pd(Ph₃)₄, Pd(OAc)₂, PdCl₂(CH₃CN), and PdCl₂(dppf) optionally in the presence of a ligand (e.g., a phosphine ligand). In other instances, a palladium pre-catalyst can be used, such as Pd₂(dba)₃ and a phosphine ligand, such as an aryl phosphine ligand, such as PPh₃ or P(o-tol)₃.

In an alternative method of preparing the donor-acceptor material comprising a polymer having a repeating unit of Formula I, the Stille coupling polymerization components are reversed. In such embodiments, the method can comprise the step of: contacting a compound represented by:

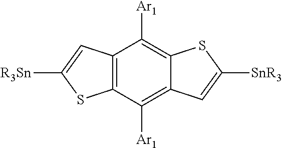

wherein R is alkyl; and Ar₁ are as described herein; and
a compound represented by

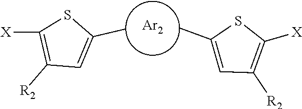

wherein X is Br, I, MsO, TfO, or OTs; and Ar₂ and R₂ are defined as described herein in the presence of a palladium catalyst thereby forming the donor-acceptor material comprising a polymer having a repeating unit of Formula I.

In certain embodiments of preparing donor-acceptor material described herein, X is Br, I, or OTs. In certain embodiments of preparing donor-acceptor material described herein, R is Me. In certain embodiments of preparing donor-acceptor material described herein, the definitions of Ar₁, Ar₂, and R₁₋₇ are as described herein.

Also provided herein, is a photoactive layer comprising at least one donor-acceptor material as described herein and at least one small molecular acceptor (SMA). The SMA can be any SMA known in the art. Preferably, the energy levels of the SMAs align with the energy levels of the donor-acceptor material as described herein. In certain embodiments, the SMA is ITIC or an analog thereof. Exemplary ITIC analogs include, but are not limited to, ITIC-Me (3,9-bis(2-methylene-((3-(1,1-dicyanomethylene)-6/7-methyl)-indanone))-5,5,11,11-tetrakis(4-hexylphenyl)-dithieno[2,3-d:2′,3′-d′]-s-indaceno[1,2-b:5,6-b′]dithiophene) and ITIC-Th (3,9-bis(2-methylene-(3-(1,1-dicyanomethylene)-indanone))-5,5,11,11-tetrakis(5-hexylthienyl)-dithieno[2,3-d:2′,3′-d′]-s-indaceno[1,2-b:5,6-b′]dithiophene).

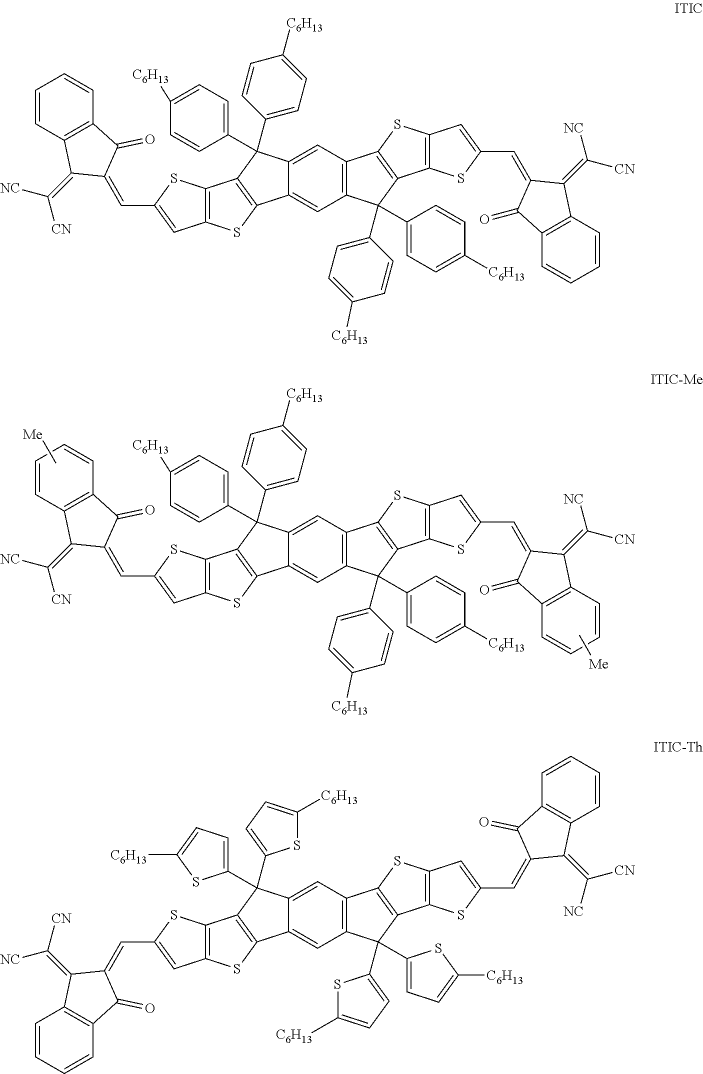

In certain embodiments, the photoactive layer comprises at least one donor-acceptor material as described herein and at least one small molecular acceptor (SMA) of Formula X:

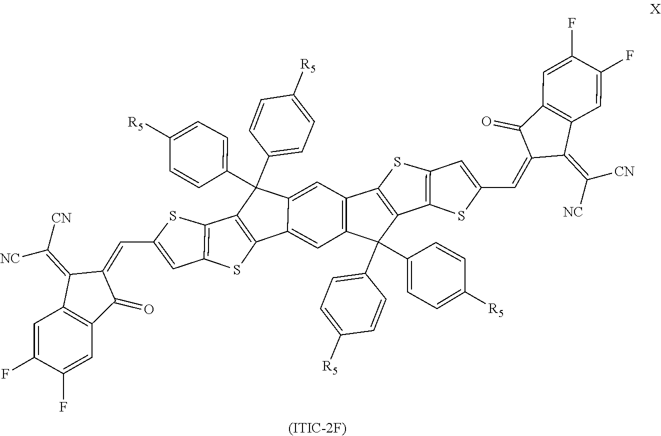

wherein R₅ for each occurrence is independently alkyl.

In certain embodiments, R₅ is a C₁-C₂₀ alkyl; C₁-C₁₈ alkyl; C₁-C₁₆ alkyl; C₁-C₁₄ alkyl; C₂-C₁₄ alkyl; C₄-C₁₄ alkyl; C₄-C₁₂ alkyl; C₄-C₁₀ alkyl; or C₄-C₈ alkyl. In certain embodiments, R₅ is n-hexyl.

In certain embodiments, the least one donor-acceptor material is a polymer having a repeating unit of Formula II:

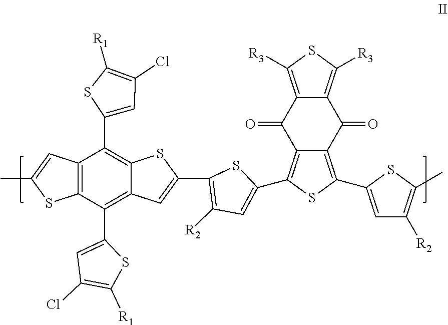

### or Formula III:

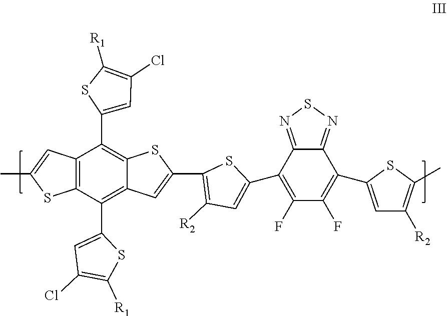

wherein R₁ is C₄-C₂₀ alkyl; R₂ is hydrogen or C₄-C₂₀ alkyl; and R₃ is C₄-C₂₀ alkyl.

In certain embodiments, the least one donor-acceptor material is a polymer having a repeating unit of Formula IV:

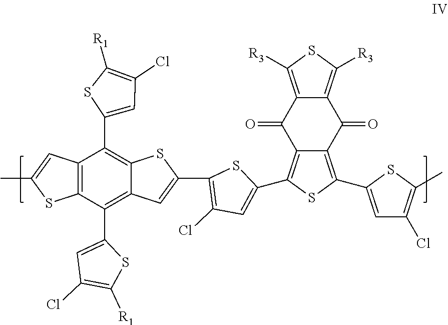

### or Formula V:

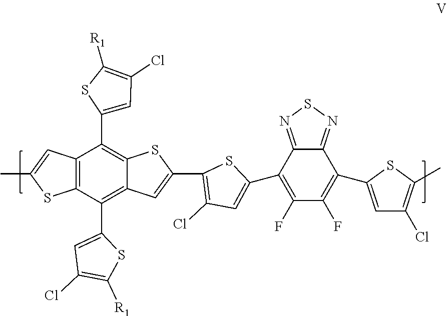

wherein R₁ is C₄-C₂₀ alkyl; and R₃ is C₄-C₂₀ alkyl.

In certain embodiments, the least one donor-acceptor material is a polymer having a repeating unit of Formula IV:

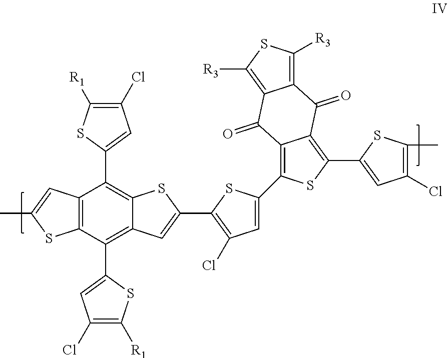

and further comprises a second repeating unit of Formula VI:

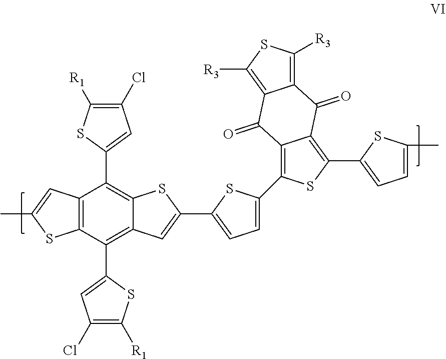

wherein R₁ is C₄-C₂₀ alkyl; and R₃ is C₄-C₂₀ alkyl.

In certain embodiments, the least one donor-acceptor material is a polymer having a repeating unit of Formula VI:

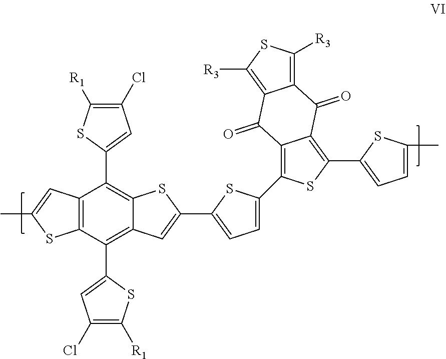

and further comprises a second repeating unit of Formula VI:

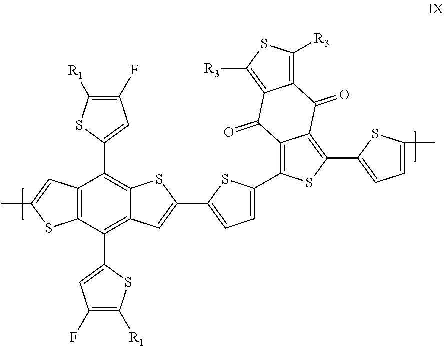

wherein R₁ is C₄-C₂₀ alkyl; and R₃ is C₄-C₂₀ alkyl.

Also provided herein is an OE device comprising at least one donor-acceptor material described herein. In certain embodiments, the OE device comprises a photoactive layer described herein. In certain embodiments, the OE device is selected from the group consisting of organic field effect transistors (OFET), integrated circuits (IC), thin film transistors (TFT), Radio Frequency Identification (RFID) tags, organic light emitting diodes (OLED), organic light emitting transistors (OLET), electroluminescent displays, organic photovoltaic (OPV) cells, organic solar cells (O-SC), flexible OPVs and O-SCs, organic laser diodes (O-laser), organic integrated circuits (O-IC), lighting devices, sensor devices, electrode materials, photoconductors, photodetectors, electrophotographic recording devices, capacitors, charge injection layers, Schottky diodes, planarising layers, antistatic films, conducting substrates, conducting patterns, photoconductors, electrophotographic devices, organic memory devices, biosensors and biochips. In certain embodiments, the OE device is a photovoltaic cell.

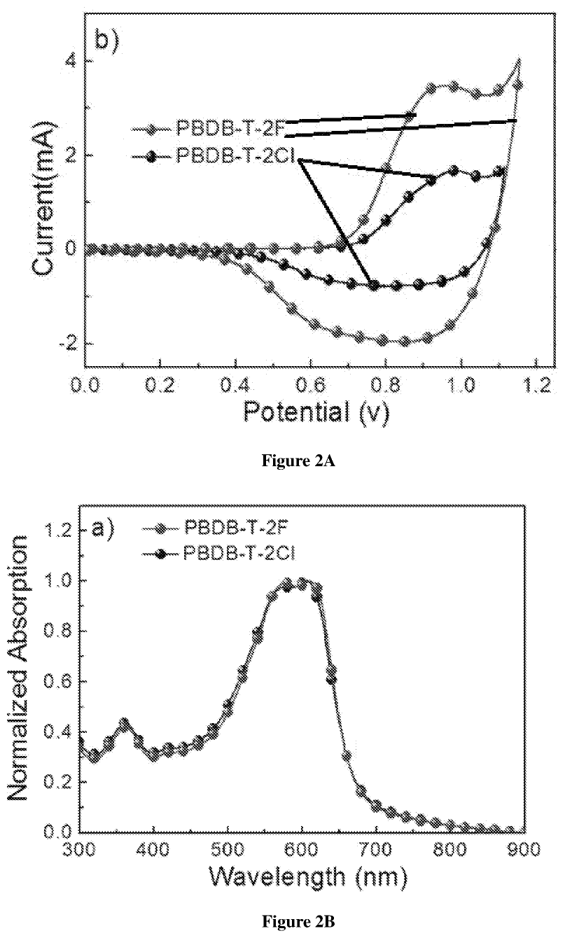

The energy levels of the HOMO and LUMO of the chlorinated BDT donor-acceptor materials described herein can be better aligned with energy levels of low bandgap SMAs. In the development of the chlorinated BDT donor-acceptor materials described herein, it was surprisingly discovered that chlorine had a larger impact on HOMO/LUMO energy levels than the corresponding fluoride analogs. Table 1 and FIG. 2a illustrates this surprising finding and shows that the energy level of the HOMO of PBDDTh-BDTEHCl is lower than the energy level of the HOMO of PBDDTh-BDTEHF.

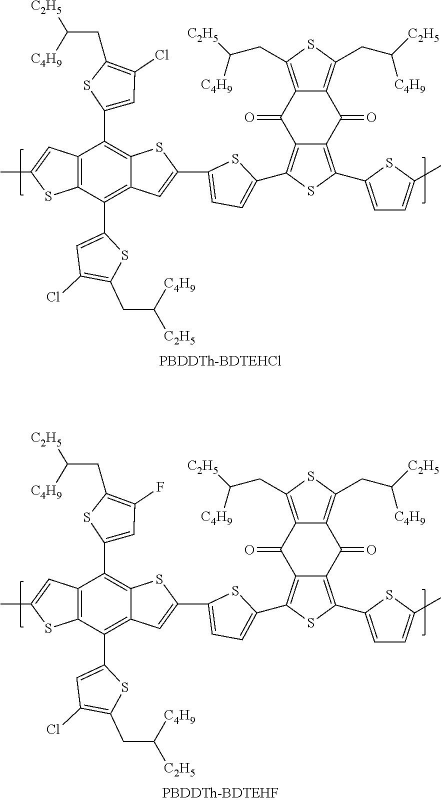

TABLE 1
Energy levels of PBDDTh-BDTEHCl and PBDDTh-BDTEHF

| | HOMO By |
|---|---|
| Donor-Acceptor Material | CV |
| PBDDTh-BDTEHCl | −5.51 eV |
| PBDDTh-BDTEHF | −5.47 eV |

Based on the relative electronegativity of fluoride (3.98, Pauling eletronegativity) and chloride (3.16, Pauling eletronegativity), it would be expected that PBDDTh-BDTEHF would have lower HOMO levels and would thus be expected to be better aligned with lower energy bandgap SMAs, such as ITIC-2F. However, experimental data establishes that this is not the case. Photoactive layers comprising PBDDTh-BDTEHF or PBDDTh-BDTEHCl with ITIC-2F exhibit similar absorption and morphologies (FIG. 2b). However, the lower energy levels of PBDDTh-BDTEHCl result in significantly higher PCEs as shown in Table 2 below.

TABLE 2
Properties of photovoltaic cells comprising donor-acceptor
materials described herein and ITIC-2F.

| | | J_{sc} | | PCE |
|---|---|---|---|---|
| Photoactive Layer | V_{oc} (V) | (mA/cm²) | FF | (%) |
| PffBT-OD-BDTCl:ITIC-2F | 0.89 | 13.4 | 0.63 | 7.6 |
| PffBT-OD-BDTBuCl:ITIC-2F | 0.89 | 16.8 | 0.64 | 9.67 |
| PBDDTh-BDTEHCl:ITIC-2F | 0.87 | 22.7 | 0.72 | 14.2 |
| PBDDThCl-BDTEHCl:ITIC-2F | 0.95 | 17.0 | 0.58 | 9.4 |
| 0.5PBDDThCl-BDTEHCl:ITIC-2F | 0.90 | 19.3 | 0.70 | 12.1 |

In further view of the surpassingly larger than expected effect of chloride substitution on the energy levels of the donor-acceptor materials described herein, the donor-acceptor PffBT-OD-BDTCl shows better device performance with higher Voc and FF compared with the corresponding comparative donor-acceptor PffBT-OD-BDTH, which does not include a chlorinated BDT unit.

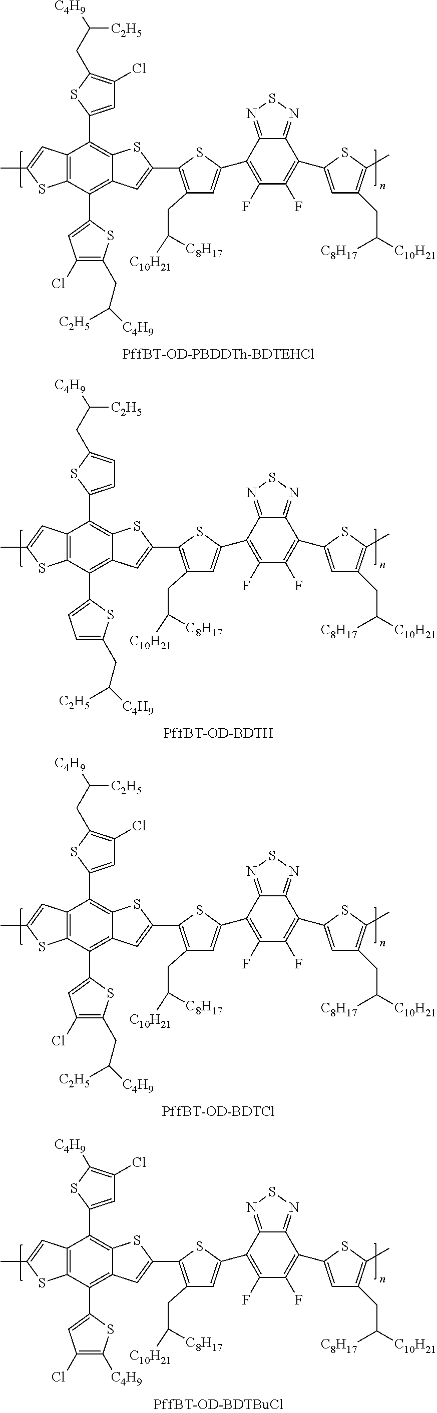

The present disclosure further relates to the use of the photoactive layer as described herein as a coating or printing ink, especially for the preparation of organic electronic (OE) devices and rigid or flexible organic photovoltaic (OPV) cells and devices and the products thereof.

In an exemplary embodiment, an OE device comprises a coating or printing ink containing the photoactive layer described herein. Another exemplary embodiment is further characterized in that the OE device is an organic field effect transistor (OFET) device. Another exemplary embodiment is further characterized in that the OE device is an organic photovoltaic (OPV) device.

Formulations of the present teachings can exhibit semiconductor behavior such as optimized light absorption/charge separation in a photovoltaic device; charge transport/recombination/light emission in a light-emitting device; and/or high carrier mobility and/or good current modulation characteristics in a field-effect device. In addition, the present formulations can possess certain processing advantages such as solution-processability and/or good stability (e.g., air stability) in ambient conditions. The formulations of the present teachings can be used to prepare either p-type (donor or hole-transporting), n-type (acceptor or electron-transporting), or ambipolar semiconductor materials, which in turn can be used to fabricate various organic or hybrid optoelectronic articles, structures and devices, including organic photovoltaic devices and organic light-emitting transistors.

Also provided is a photovoltaic cell comprising the photoactive layer described herein. The photovoltaic cell can be a single junction, double junction, or multi-junction cell.

An exemplary single junction photovoltaic cell is depicted in FIG. 5. The photovoltaic cell can comprise a transparent cathode 150, an electron transport layer 140, the photoactive layer described herein 130, an anode interlayer 120, and an anode 110.

The transparent cathode 150 may generally include any transparent or semi-transparent conductive material. Indium tin oxide (ITO) can be used for this purpose, because it is substantially transparent to light transmission and thus facilitates light transmission through the ITO cathode layer to the photoactive layer without being significantly attenuated. The term “transparent” means allowing at least 50 percent, commonly at least 80 percent, and more commonly at least 90 percent, of light in the wavelength range between 350-750 nm to be transmitted.

In certain embodiments, the electron transport layer 150 comprises at least one material selected from the group consisting of zinc oxide (ZnO), tin oxide (SnO₂), lithium fluoride (LiF), zinc indium tin oxide (ZITO), poly[(9,9-bis(3′-(N,N-dimethylamino)propyl)-2,7-fluorene)-alt-2,7-(9,9-dioctylfluorene)] (PFN), poly[(9,9-bis(3′-((N,N-dimethyl)-N-ethylammonium)-propyl)-2,7-fluorene)-alt-2,7-(9,9-dioctylfluorene)] (PFN-Br), and poly[9,9-bis(6′-(N,N-diethylamino)propyl)-fluorene-alt-9,9-bis(3-ethyl(oxetane-3-ethyloxy)-hexyl)-fluorene] (PFN-OX). In certain embodiments, the electron transport layer is ZnO.

The anode interlayer 120 can comprises at least one material selected from the group consisting of poly(3,4-ethylenedioxythiophene)-poly(styrenesulfonate) (PEDOT:PSS), polyanaline (PANI), vanadium (V) oxide (V₂O₅), molybdenum oxide (MoO₃), and Tungsten oxide (WO₃). In certain embodiments, the anode interlayer is vanadium (V) oxide (V₂O₅), molybdenum oxide (MoO₃).

The anode 110 can comprise any anodic material known to those of skill in the art. In certain embodiments, the anode comprises aluminum, gold, copper, silver, or a combination thereof. In certain embodiments, the anode comprises aluminum.

Depending on the composition of the electron transport layer 150, it can be made using any method known in the art, such as by sequential physical vapor deposition, chemical vapor deposition, sputtering, and the like.

In instances in which the electron transport layer 150 comprises ZnO, it can be prepared by depositing a solution comprising an electron transport layer precursor. In such embodiments, the electron transport layer is prepared by the deposition of a solution comprising an organic zinc compound in an organic solvent on the surface of the transparent cathode and annealing the deposited organic zinc compound solution at a temperature of 60 to 120; 70 to 120; 80 to 120; 80 to 110 or 80 to 100° C. thereby forming the electron transport layer 150. Suitable organic zinc compounds include any aryl, alkyl, cycloalkyl, alkenyl, and alkynyl zinc species. In certain embodiments, the organic zinc compound is a dialkyl zinc compound, such as dimethyl or diethyl zinc. Due to the reactivity of the organic zinc compound, it is typically deposited from an anhydrous solvent, such as an ether, alkane, and/or aromatic solvent. In the examples below, a solution of diethyl zinc in tetrahydrofuran is deposited on the ITO layer by spin coating. The deposited thin layer of diethyl zinc is then annealed at a temperature of 60 to 120; 70 to 120; 80 to 120; 80 to 110 or 80 to 100° C.

The photoactive layer comprising the at least one donor-acceptor material as described herein and at least one SMA can be prepared by forming a photoactive layer solution comprising the at least one SMA and at least one donor-acceptor material and depositing the photoactive layer solution onto the electron transport layer 150 and optionally annealing the applied photoactive layer solution thereby forming the photoactive layer.

The solvent used to prepare the photoactive layer solution can be a solvent in which the at least one SMA and at least one donor-acceptor material are substantially soluble in when solvent is heated above room temperature. The solvent can be 1,2-dichlorobenzene, 1,3-dichlorobenzene, 1,2,4-trichlorobenzene, chlorobenzene, 1,2,4-trimethylbenzene, chloroform and combinations thereof. In certain embodiments, the photoactive layer solution further comprises one or more solvent additives, such as 1-chloronaphthalene and 1,8-octanedithiol, 1,8-diiodooctane, and combinations thereof. In certain embodiments, the solvent is at least one of 1,2-dichlorobenzene and chlorobenzene and optionally contains the solvent additive 1,8-diiodooctane. In instances where the solvent further comprises a solvent additive, the solvent additive can be present between about 0.1% to about 8% (v/v); about 0.1% to about 6% (v/v); about 0.1% to about 4% (v/v); or about 0.1% to about 2% (v/v) in the solvent.

The photoactive layer solution can be deposited on the substrate using any method known to those of skill in the art including, but not limited to, spin coating, printing, print screening, spraying, painting, doctor-blading, slot-die coating, and dip coating.

Once the photoactive layer solution is deposited, the solvent can be removed (e.g., at atmospheric pressure and temperature or under reduced pressure and/or elevated temperature) thereby forming the thin film comprising the donor-acceptor material and optionally be annealed. The step of annealing can occur at 80 to 150° C.; 80 to 120° C.; or 90 to 110° C.

In embodiments in which the anode interlayer 140 comprises vanadium (V) oxide (V₂O₅), molybdenum oxide (MoO₃), the anode interlayer can be deposited by sequential thermal evaporation of the e.g., vanadium (V) oxide (V₂O₅), molybdenum oxide (MoO₃) onto photoactive layer 130.

The anode 110 can be deposited on the anode interlayer 140 using any method known in the art, such as by physical vapor deposition, chemical vapor deposition, or sputtering. In the examples below, an aluminum anode is deposited using thermal vaporization.

Photovoltaic cells comprising the photoactive layers described herein exhibit amongst some of the highest PCEs of OPV devices. Table 1 presents the photovoltaic properties of exemplary photovoltaic cells.

### EXAMPLES

### Example 1—Synthetic Route of BDT-Eh-SnMe₃

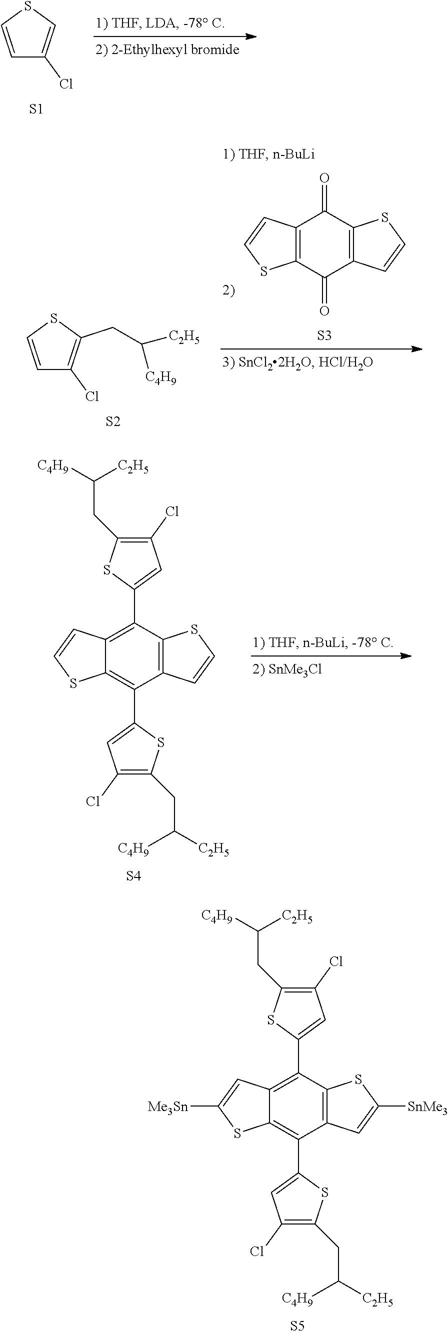

### Step 1: Preparation of 3-chloro-2-(2-ethylhexyl)thiophene (S2)

3-chlorothiophene (5.0 g, 42 mmol) was dissolve in 100 ml tetrahydrofuran under nitrogen protection, and the solution was cooled to minus 78° C. and lithium diisopropylamide (LDA) (2M, 23 ml) was added to the solution dropwise. 2-ethylhexyl bromide (9.7 g, 50 mmol) was add to the mixture subsequently. The mixture was then allowed to warm up to room temperature and stirred overnight. 50 ml brine was then added to the solution to quench the reaction and ether (50 ml×3) was used to extract the mixture. The organic layer was dried by Na₂SO₄. Solvent was removed through evaporation. The mixture was further purified through reduced pressure distillation to get the colorless oil (6.6 g, 68%). 1H NMR (400 MHz, CDCl3), δ(ppm): 7.10 (d, 2H), 6.85 (d, 2H), 2.73-2.71 (d, 2H), 1.63 (m, 1H), 1.30 (m, 8H), 0.89 (m, 6H).

### Step 2: Preparation of 4,8-bis(4-chloro-5-(2-ethylhexyl)thiophen-2-yl)benzo [1,2-b:4,5-b]dithiophene (S4)

A Solution of S2 (2.3 g, 10.0 mmol) in 150 ml THF was under N₂. The n-butyllithium (2M, 5 ml) was added dropwise to the solution under minus 78 degree and the solution was stirred for 1 hours. Then, S3 (1.0 g, 4.5 mmol) was added to the mixture and stirred at 50 degree overnight. The SnCl₂. 2H₂O (10.0 g) in HCl/H₂O (25/25 ml) Solution for 2 h at room temperature. Then the mixture was extracted by 50 ml chloroform for 3 times and washed by water and brine. The organic layer was dried over Na₂SO₄ and remove solvent. Then the crude was further purified through column to get yellow solid (1.2 g, 42%). 1H NMR (400 MHz, CDCl3), δ(ppm): 7.62-7.60 (d, 2H), 7.50-7.48 (d, 2H), 7.23 (s, 2H), 2.85-2.83 (d, 4H), 1.74 (m, 2H), 1.39 (m, 16H), 0.98-0.92 (m, 12H).

### Step 3: Preparation of (4,8-bis(4-chloro-5-(2-ethylhexyl)thiophen-2-yl)benzo [1,2-b:4,5-b]dithiophene-2,6-diyl)bis(trimethylstannane) (S5)

A Solution of S4 (0.80 g, 1.2 mmol) in 50 ml THF was under N₂. n-butyllithium (2M, 2.4 ml) was added dropwise to the solution under minus 78 degree and the solution was stirred for 4 hours. Then, SnMeCl₃ (1M, 3 ml) was added to the mixture and stirred at room temperature overnight. The mixture was treated with KF Solution and was extracted by chloroform for 3 times and washed by water and brine. The organic layer was dried over Na₂SO₄ and remove solvent. Then the crude was further purified through recrystallization to get light yellow solid (0.82 g, 64%). 1H NMR (400 MHz, Acetone-d), δ(ppm): 7.76-7.69 (t, 2H), 7.36 (s, 2H), 2.93-2.89 (m, 4H), 1.79 (m, 2H), 1.51-1.37 (m, 16H), 0.99-0.90 (m, 12H), 0.43 (t, 18H).

### Example 2—Synthetic Route of BDT-Bu-SnMe₃

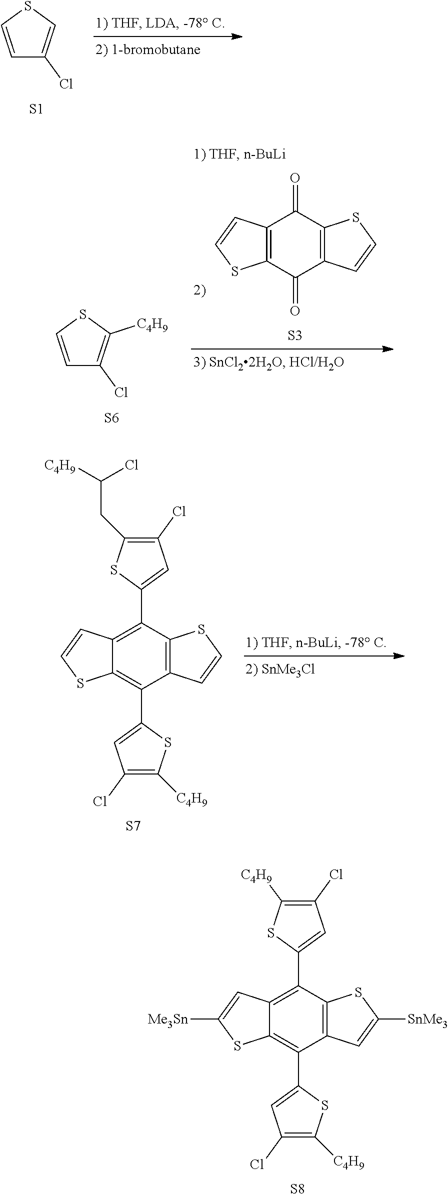

### Step 1: Preparation of 2-butyl-3-chlorothiophene (S6)

3-chlorothiophene (5.0 g, 42 mmol) was dissolve in 100 ml tetrahydrofuran under nitrogen protection, and the solution was cooled to minus 78 degree and lithium diisopropylamide (LDA) (2M, 23 ml) was added to the solution dropwise. 1-bromobutane (6.9 g, 50 mmol) was add to the mixture subsequently. The mixture then allow to warm up to room temperature and stir over night. The 50 ml brine was added to the solution to quench the reaction and use ether (50 ml×3) to extract the mixture. The organic layer was dried by Na₂SO₄. Solvent was removed through evaporation. The mixture was further purified through reduced pressure distillation to get the colorless oil (5.2 g, 71%).

### Step 2: Preparation of 4,8-bis(5-butyl-4-chlorothiophen-2-yl)benzo[1,2-b:4,5-b]dithiophene (S7)

A Solution of S6 (1.7 g, 10.0 mmol) in 150 ml THF was under N₂. The n-butyllithium (2M, 5 ml) was added dropwise to the solution under minus 78° C. and the solution was stirred for 1 hours. Then, S3 (1.0 g, 4.5 mmol) was added to the mixture and stirred at 50 C overnight. The SnCl₂.2H₂O (10.0 g) in HCl/H₂O (25/25 ml) Solution for 2 h at room temperature. Then the mixture was extracted by 50 ml chloroform for 3 times and washed by water and brine. The organic layer was dried over Na₂SO₄ and remove solvent. Then the crude was further purified through column to get yellow solid (0.92 g, 38%). 1H NMR (400 MHz, CDCl₃), δ(ppm): 7.62-7.60 (d, 2H), 7.50-7.48 (d, 2H), 7.23 (s, 2H), 2.92-2.88 (m, 4H), 1.75 (m, 4H), 1.50 (m, 4H), 1.02-0.98 (m, 6H).

### Step 3: Preparation of (4,8-bis(5-butyl-4-chlorothiophen-2-yl)benzo[1,2-b:4,5-b]dithiophene-2,6-diyl)bis(trimethylstannane) (S8)

A Solution of S7 (0.64 g, 1.2 mmol) in 50 ml THF was under N₂. n-butyllithium (2M, 2.4 ml) was added dropwise to the solution under minus 78° C. and the solution was stirred for 4 hours. Then, SnMeCl₃ (1M, 3 ml) was added to the mixture and stirred at room temperature overnight. The mixture was treated with KF solution and was extracted by chloroform for 3 times and washed by water and brine. The organic layer was dried over Na₂SO₄ and remove solvent. Then the crude was further purified through recrystallization to get light yellow solid (0.78 g, 76%). 1H NMR (400 MHz, CDCl₃), δ(ppm): 7.65-7.58 (t, 2H), 7.23 (s, 2H), 2.92-2.82 (m, 4H), 1.75 (m, 4H), 1.46-1.44 (m, 4H), 1.01-0.91 (m, 6H), 0.43 (t, 18H).

### Example 2—Synthesis of PffBT-OD-BDTCI

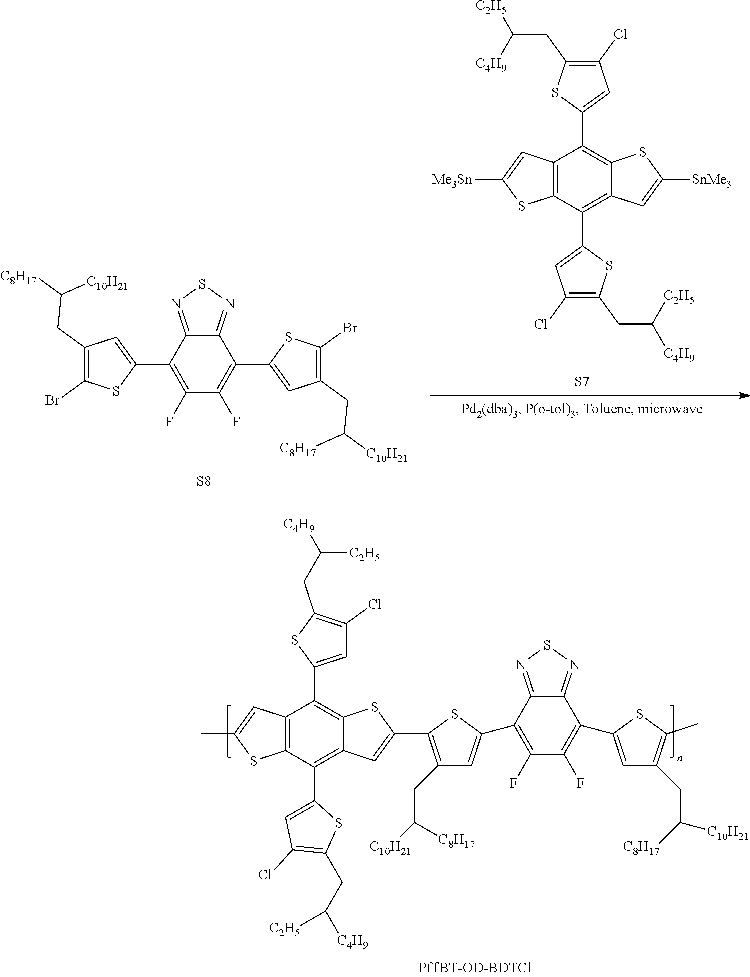

A mixture of S7 (21.6 mg, 0.0222 mmol), S8 (23.4 mg, 0.0222 mmol), Pd₂(dba)₃ (0.5 mg, 0.0005 mmol) and P(o-tol)₃ (1.0 mg, 0.0033 mmol) was placed in a microwave tube. Toluene (0.2 mL) was added in a glove box that was filled with nitrogen. The tube was sealed and heated to 140° C. for 1 d. The obtained deep green gel was diluted with 20 mL hot chlorobenzene and the solution was precipitated into methanol. The solid was collected by filtration, and loaded into a thimble in a Soxhlet extractor. The crude polymer was extracted successively with acetone, chloroform. The chloroform solution was concentrated by evaporation, re-dissolved in hot chlorobenzene and precipitated into methanol. The solid was collected by filtration and dried in vacuo to get the polymer as black solid.

### Example 3—Synthesis of PBDDTh-BDTEHCl

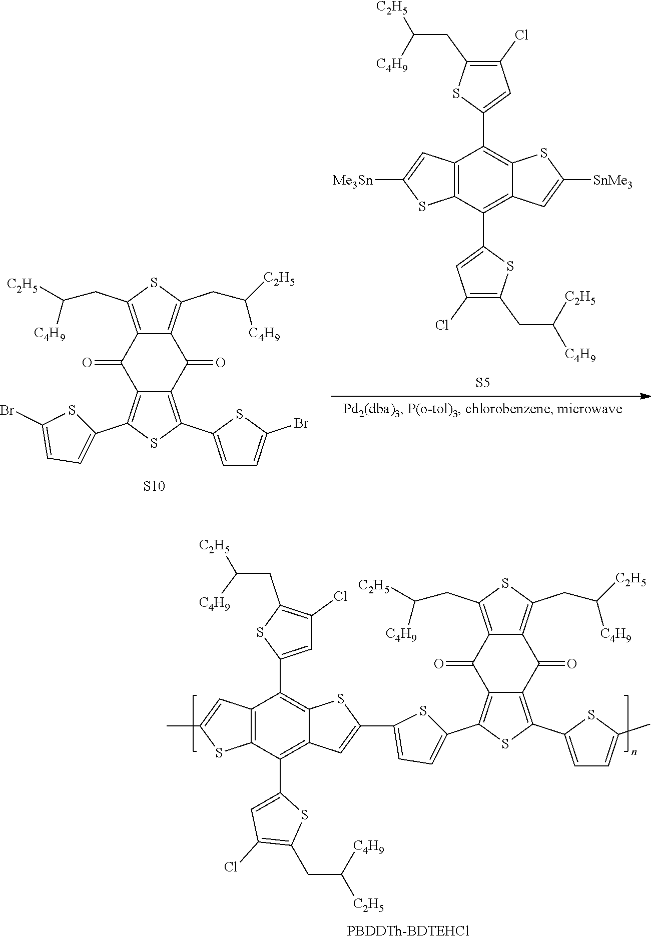

A mixture of S5 (21.6 mg, 0.0222 mmol), S10 (17.2 mg, 0.0222 mmol), Pd₂(dba)₃ (0.5 mg, 0.0005 mmol) and P(o-tol)₃ (1.0 mg, 0.0033 mmol) was placed in a microwave tube. Chlorobenzene (0.2 mL) was added in a glove box which is filled with nitrogen. The tube was sealed and heated to 140° C. for 1 d. The obtained deep blue gel was diluted with 20 mL hot chlorobenzene and the solution was precipitated into methanol. The solid was collected by filtration and loaded into a thimble in a Soxhlet extractor. The crude polymer was extracted successively with acetone, chloroform. The chloroform solution was concentrated by evaporation, re-dissolved in hot chlorobenzene and precipitated into methanol. The solid was collected by filtration and dried in vacuo to get the polymer as black solid.

### Example 4—Synthesis of PBDDThCl-BDTEHCI

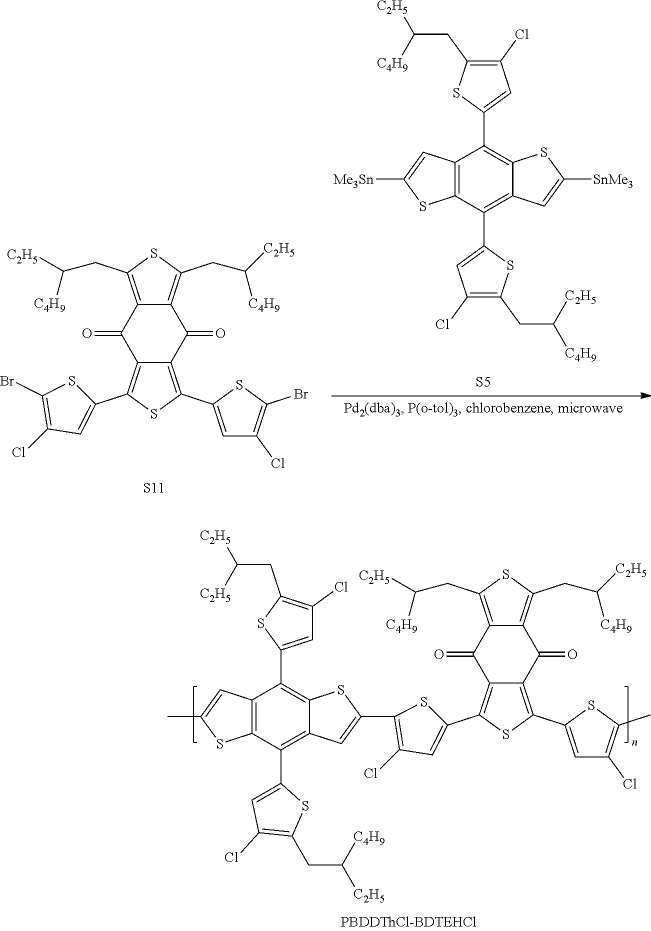

A mixture of S5 (21.6 mg, 0.0222 mmol), S11 (18.6 mg, 0.0222 mmol), Pd₂(dba)₃ (0.5 mg, 0.0005 mmol) and P(o-tol)₃ (1.0 mg, 0.0033 mmol) was placed in a microwave tube. Chlorobenzene (0.2 mL) was added in a glove box which is filled with nitrogen. The tube was sealed and heated to 140° C. for 1 d. The obtained deep blue gel was diluted with 20 mL hot chlorobenzene and the solution was precipitated into methanol. The solid was collected by filtration and loaded into a thimble in a Soxhlet extractor. The crude polymer was extracted successively with acetone, chloroform. The chloroform solution was concentrated by evaporation, re-dissolved in hot chlorobenzene and precipitated into methanol. The solid was collected by filtration and dried in vacuo to get the polymer as black solid.

### Example 5—Synthesis of 0.5PBDDThCl-BDTEHCI

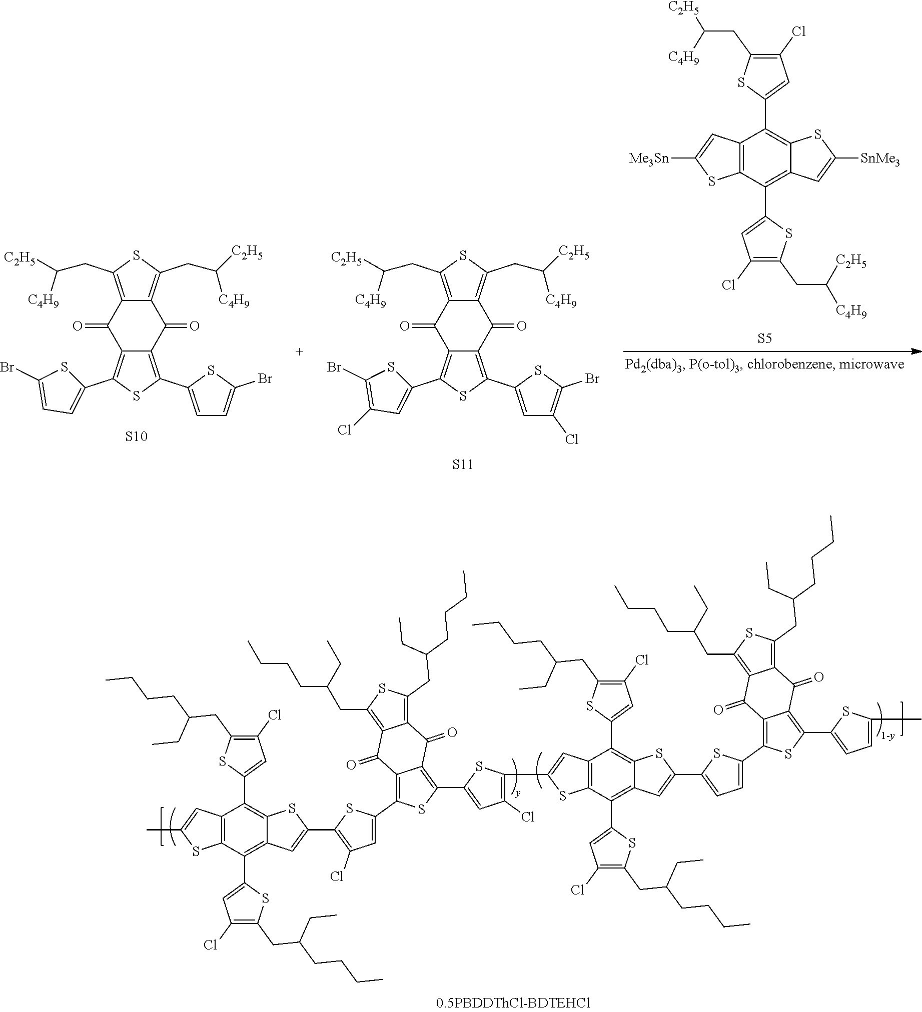

A mixture of S5 (21.6 mg, 0.0222 mmol), S11 (9.3 mg, 0.0111 mmol), S10 (8.6 mg, 0.0111 mmol), Pd₂(dba)₃ (0.5 mg, 0.0005 mmol) and P(o-tol)₃ (1.0 mg, 0.0033 mmol) was placed in a microwave tube. Chlorobenzene (0.2 mL) was added in a glove box that was filled with nitrogen. The tube was sealed and heated to 140° C. for 1 d. The obtained deep blue gel was diluted with 20 mL hot chlorobenzene and the solution was precipitated into methanol. The solid was collected by filtration and loaded into a thimble in a Soxhlet extractor. The crude polymer was extracted successively with acetone, chloroform. The chloroform solution was concentrated by evaporation, re-dissolved in hot chlorobenzene and precipitated into methanol. The solid was collected by filtration and dried in vacuo to get the polymer as black solid.

### Example 6—Synthesis of 0.5PBDDTh-BDTEHCl

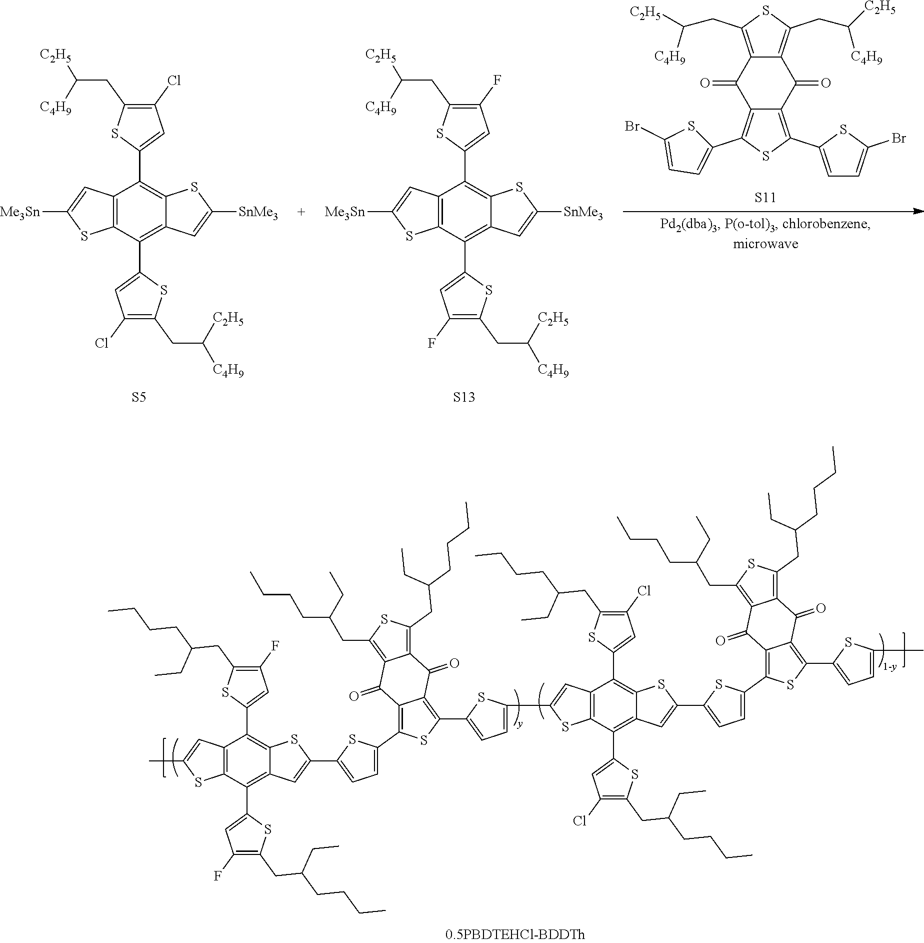

A mixture of S5 (23.4 mg, 0.0240 mmol), S13 (22.6 mg, 0.0240 mmol), S11 (36.8 mg, 0.0480 mmol), Pd₂(dba)₃ (0.5 mg, 0.0005 mmol) and P(o-tol)₃ (1.0 mg, 0.0033 mmol) was placed in a microwave tube. Chlorobenzene (0.3 mL) was added in a glove box that was filled with nitrogen. The tube was sealed and heated to 140° C. for 1 d. The obtained deep blue gel was diluted with 20 mL hot chlorobenzene and the solution was precipitated into methanol. The solid was collected by filtration and loaded into a thimble in a Soxhlet extractor. The crude polymer was extracted successively with acetone, chloroform. The chloroform solution was concentrated by evaporation, re-dissolved in hot chlorobenzene and precipitated into methanol. The solid was collected by filtration and dried in vacuo to get the polymer as black solid.

### Example 7—Characterization of Polymer Donor

### Example 7a: Optical Properties

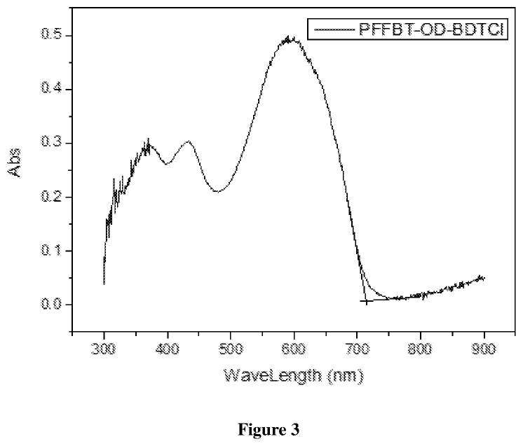

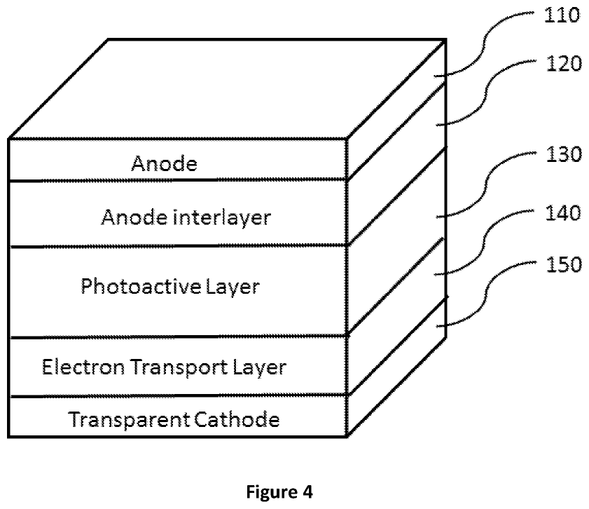

Optical absorption measurements of small molecular acceptor from Example 1 were carried out using a Cary UV-vis spectrometer on DCB solution of the polymer. The onset of the absorption is used to estimate the bandgap, which is depicted in FIG. 3 for exemplary donor-acceptor material PFFBT-OD-BDTCl.

### Example 8—Device Fabrication

### Example 8a: Photovoltaic Cell Fabrication and Measurements

Pre-patterned ITO-coated glass with a sheet resistance of ˜15Ω/square was used as the substrate. It was cleaned by sequential sonication in soap deionized water, deionized water, acetone, and isopropanol. After UV/ozone treatment for 60 min, a ZnO electron transport layer was prepared by spin-coating at 5000 rpm from a ZnO precursor solution (diethyl zinc). Photoactive layer solutions were prepared in chlorobenzene/dichlorobenzene or chlorobenzene/dichlorobenzene/1,8-diiodooctane with various ratios (polymer concentration: 7-12 mg/mL). To completely dissolve the polymer, the photoactive layer solution can be stirred on hotplate at 100-120° C. for at least 3 hours. Photoactive layers were spin-coated from warm solutions in a N₂ glovebox at 600-850 rpm to obtain a film having a thicknesses of ˜100 nm. The donor-acceptor material/SMA photoactive layers were then optionally annealed at 100° C. for 5 min before being transferred to a vacuum chamber of a thermal evaporator inside the same glovebox. At a vacuum level of 3×10⁻⁶ Torr, a thin layer (20 nm) of MoO₃ or V₂O₅ was deposited as the anode interlayer, followed by deposition of 100 nm of Al as the top electrode. All cells were encapsulated using epoxy inside the glovebox. Device J-V characteristics was measured under AM1.5G (100 mW/cm²) using a Newport solar simulator. The light intensity was calibrated using a standard Si diode (with KG5 filter, purchased from PV Measurement) to bring spectral mismatch to unity. J-V characteristics were recorded using a Keithley 236 source meter unit. Typical cells have devices area of about 5.9 mm², which is defined by a metal mask with an aperture aligned with the device area. EQEs were characterized using a Newport EQE system equipped with a standard Si diode. Monochromatic light was generated from a Newport 300 W lamp source. The V_{OC}, J_{SC}, FF and PCE of exemplary photovoltaic devices described herein are summarized in Table 1 above.

What is claimed is:

1. A donor-acceptor material comprising a polymer having a repeating unit of Formula I: 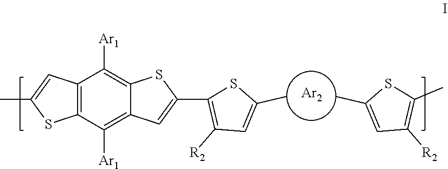
wherein Ar₁ is selected from the group consisting of: 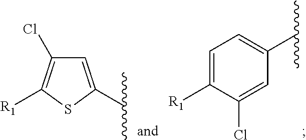
Ar₂ is selected from the group consisting of: 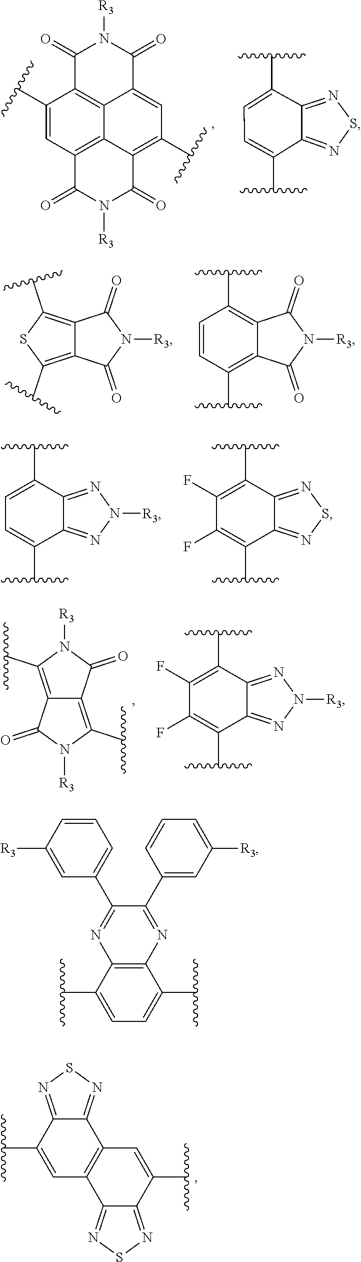 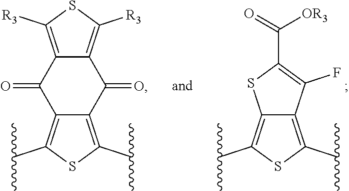
R₁ for each occurrence is independently selected from the group consisting of straight-chain, branched or cyclic alkyl groups with 2-40 C atoms, wherein one or more non-adjacent C atoms is optionally replaced by —O—, —S—, —(C═O)—, —C(═O)O—, —OC(═O)—, —O(C═O)O—, —CR₄═CR₄—, or —C≡C—, and one or more H atoms are optionally replaced by F, Cl, Br, I, CN, aryl, heteroaryl, aryloxy, heteroaryloxy, arylcarbonyl, heteroarylcarbonyl, arylcarbonyloxy, heteroarylcarbonyloxy, aryloxycarbonyl, or heteroaryloxycarbonyl having 4 to 30 ring atoms unsubstituted or substituted by one or more non-aromatic groups;
R₂ for each occurrence is independently selected from the group consisting of hydrogen, chloride, straight-chain, branched or cyclic alkyl groups with 2-40 C atoms, wherein one or more non-adjacent C atoms is optionally replaced by —O—, —S—, (C═O)—, —C(═O)O—, —OC(═O)—, —O(C═O)O—, —CR₄═CR₄—, or —C≡C—, and one or more H atoms are optionally replaced by F, Cl, Br, I, CN, aryl, heteroaryl, aryloxy, heteroaryloxy, arylcarbonyl, heteroarylcarbonyl, arylcarbonyloxy, heteroarylcarbonyloxy, aryloxycarbonyl, or heteroaryloxycarbonyl having 4 to 30 ring atoms unsubstituted or substituted by one or more non-aromatic groups;
R₃ for each instance is independently alkyl; and
R₄ for each instance is independently hydrogen or alkyl.

2. The donor-acceptor material of claim 1, wherein R₂ for each occurrence is independently hydrogen or alkyl.

3. The donor-acceptor material of claim 2, wherein R₁ is alkyl.

4. The donor-acceptor material of claim 3, wherein Ar₁ is:

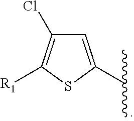

5. The donor-acceptor material of claim 3, wherein the polymer has a repeating unit of Formula II: 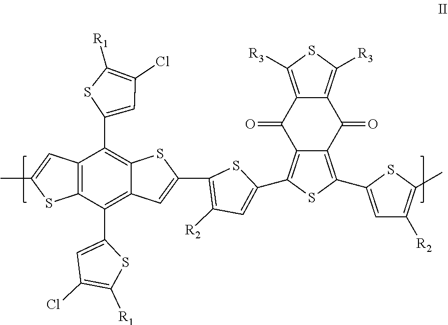
or Formula III: 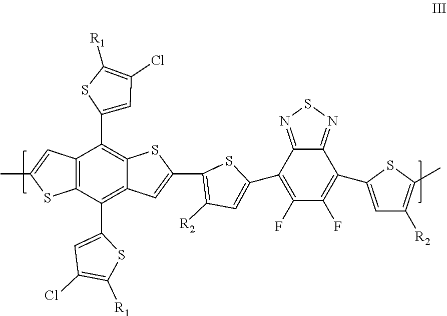
wherein R₁ is C₄-C₂₀ alkyl;
R₂ is hydrogen or C₄-C₂₀ alkyl; and
R₃ is C₄-C₂₀ alkyl.

6. The donor-acceptor material of claim 1, wherein the polymer has a repeating unit represented by:

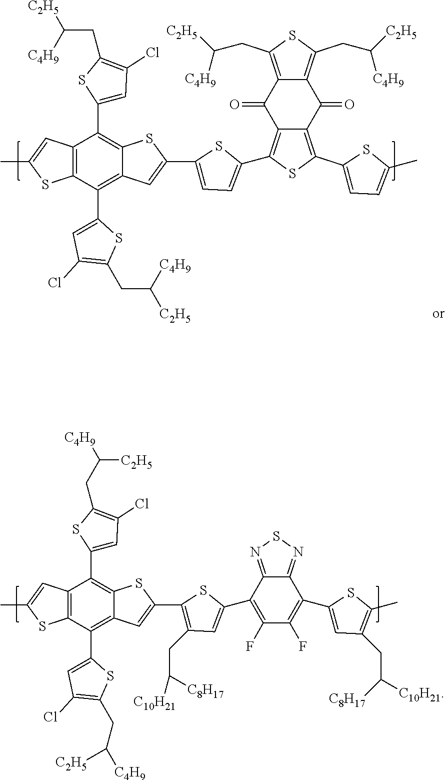

7. The donor-acceptor material of claim 1, wherein R₂ is chloride and Ar₁ is:

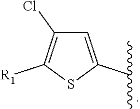

8. The donor-acceptor material of claim 7, wherein R₁ is alkyl.

9. The donor-acceptor material of claim 8, wherein the polymer has a repeating unit of Formula IV: 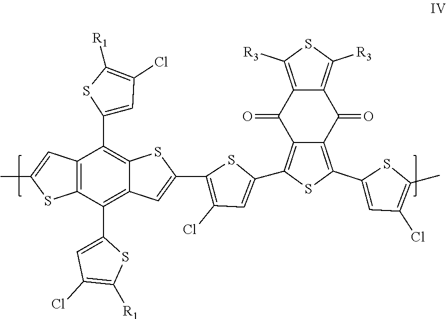
or Formula V: 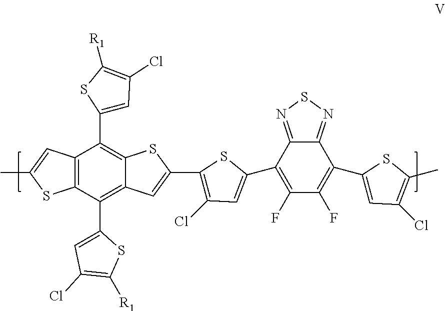
wherein R₁ is C₄-C₂₀ alkyl; and
R₃ is C₄-C₂₀ alkyl.

10. The donor-acceptor material of claim 9, wherein R₁ and R₃ are 2-ethylhexyl.

11. The donor-acceptor material of claim 9, wherein the polymer has a repeating unit of Formula IV: 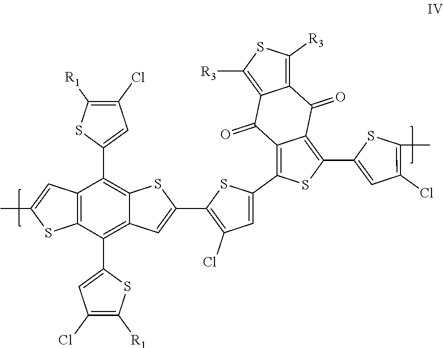
and further comprises a second repeating unit of Formula VI: 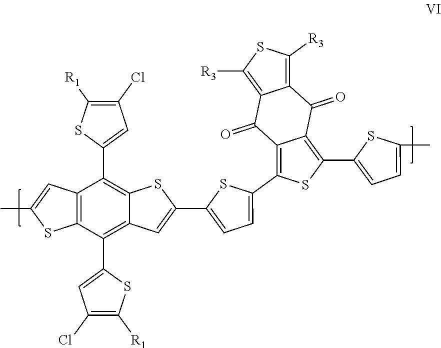
wherein R₁ is C₄-C₂₀ alkyl; and
R₃ is C₄-C₂₀ alkyl.

12. The donor-acceptor material of claim 11, wherein R₁ and R₃ are 2-ethylhexyl.

13. The donor-acceptor material of claim 11, wherein the molar ratio of the repeating unit of Formula IV and Formula VI is 0.2:1 to 0.7:1.

14. The donor-acceptor material of claim 9, wherein the polymer has a repeating unit of Formula VI: 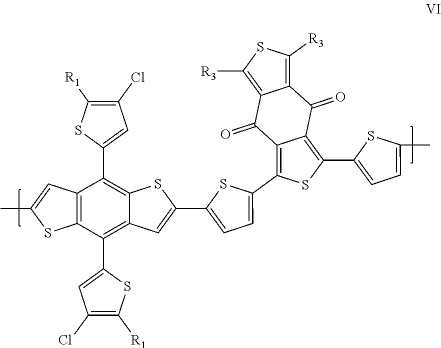
and further comprises a second repeating unit of Formula IX: 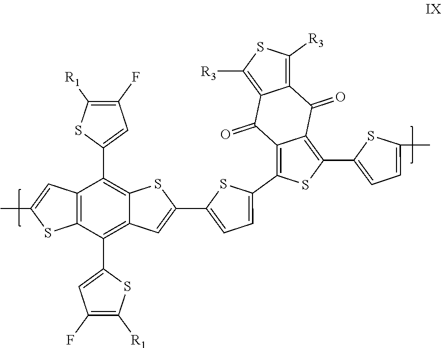
wherein R₁ is C₄-C₂₀ alkyl; and
R₃ is C₄-C₂₀ alkyl.

15. A photoactive layer comprising at least one donor-acceptor material of claim 1 and at least one small molecular acceptor (SMA) of Formula X: 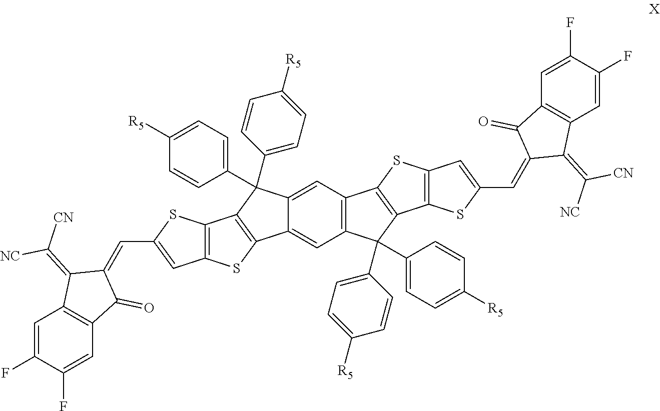
wherein R₅ for each occurrence is independently alkyl.

16. The photoactive layer of claim 14, wherein the least one donor-acceptor material is a polymer having a repeating unit of Formula II: 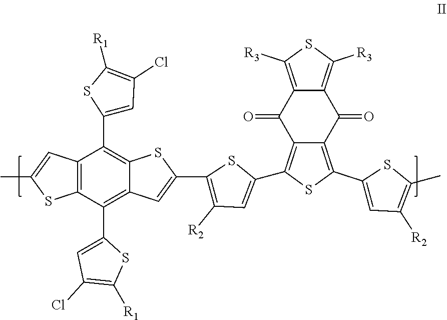
or Formula III: 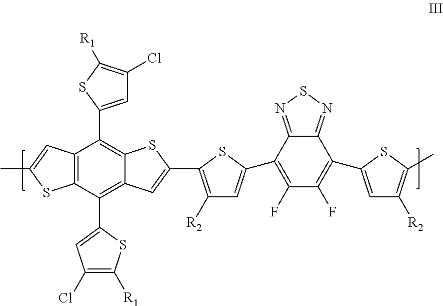
wherein R₁ is C₄-C₂₀ alkyl;
R₂ is hydrogen or C₄-C₂₀ alkyl; and
R₃ is C₄-C₂₀ alkyl.

17. The photoactive layer of claim 14, wherein the least one donor-acceptor material is a polymer having a repeating unit of Formula IV: 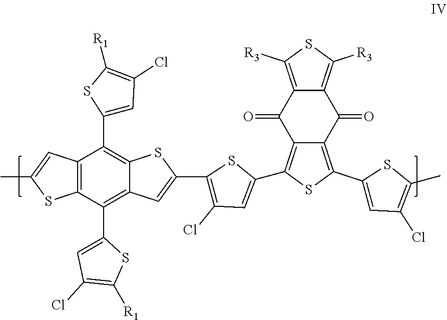
or Formula V: 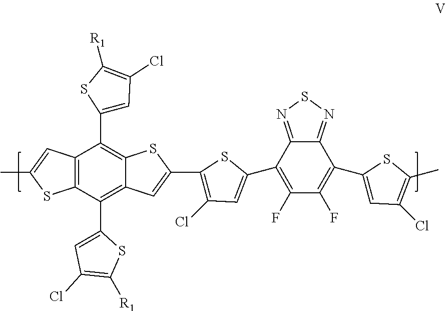
wherein R₁ is C₄-C₂₀ alkyl; and
R₃ is C₄-C₂₀ alkyl.

18. The photoactive layer of claim 14, wherein the least one donor-acceptor material is a polymer having a repeating unit of Formula IV: 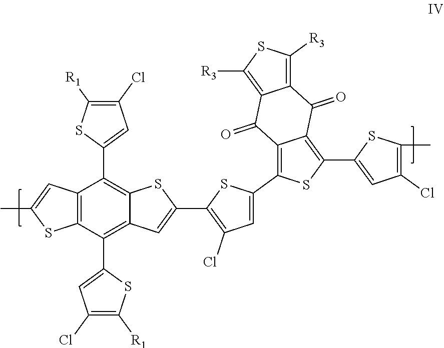
and further comprises a second repeating unit of Formula VI: 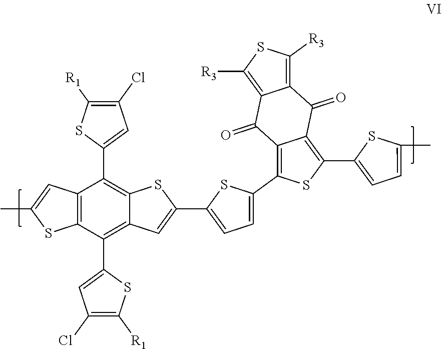
wherein R₁ is C₄-C₂₀ alkyl; and
R₃ is C₄-C₂₀ alkyl; or
a polymer having a repeating unit of Formula VI: 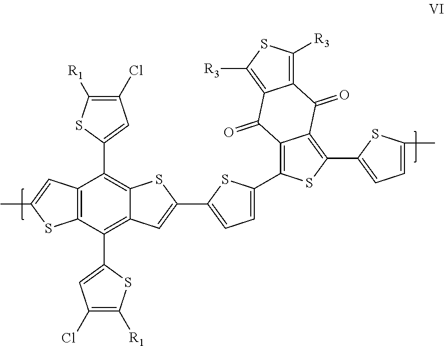
and further comprises a second repeating unit of Formula IX: 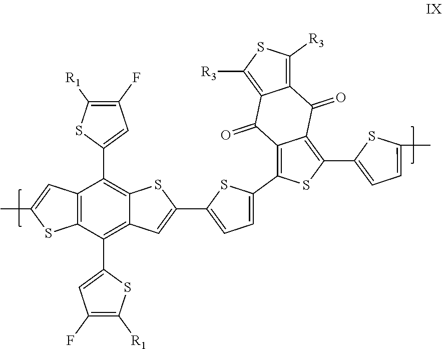
wherein R₁ is C₄-C₂₀ alkyl; and
R₃ is C₄-C₂₀ alkyl.

19. A photovoltaic cell comprising the photoactive layer of claim 15.

20. A photovoltaic cell comprising the photoactive layer of claim 17.

21. A photovoltaic cell comprising the photoactive layer of claim 18.
